(19) United States
(12) Patent Application Publication
(10) Pub. No.: US 2026/0056232 A1
(43) Pub. Date: Feb. 26, 2026

(54) ELECTRICALLY CONDUCTIVE CONTACT PIN

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Chang Hee HONG, Gyeonggi-do (KR)

(73) Assignee: POINT ENGINEERING CO., LTD., Chungcheongnam-do (KR)

(21) Appl. No.: 18/992,993

(22) PCT Filed: Jul. 5, 2023
(86) PCT No.: PCT/KR2023/009450

§ 371 Date: Oct. 30, 2025

(30) Foreign Application Priority Data
Jul. 12, 2022 (KR) 10-2022-0085867

(51) Int. Cl. G01R 1/067

(52) U.S. Cl. CPC G01R 1/06733; G01R 1/06716; G01R 1/06761

(57) ABSTRACT

The present invention relates to an electrically conductive contact pin provided with an elastic portion, wherein the elastic portion includes: a plurality of straight portions; and a plurality of curved portions connecting the straight portions adjacent to each other above and below, and further includes a slit portion for dividing the curved portions into split beam portions, a stopper for limiting an elastic deformation position, or a groove portion for forming a cut portion on the inner surface of the curved portions. The purpose of the present invention is to improve the inspection reliability of an inspection object and to prevent damage to the inspection object by facilitating elastic deformation.

### CROSS-REFERENCES

This application is a 371 of international application of PCT application serial no. PCT/KR2023/009450, filed on Jul. 5, 2023, which claims the priority benefit of Korea application no. 10-2022-0085867, filed on Jul. 12, 2022. The entirety of each of the above mentioned patent applications is hereby incorporated by reference herein and made a part of this specification.

### TECHNICAL FIELD

The present disclosure relates to an electrically conductive contact pin.

### DESCRIPTION OF RELATED ART

Electrical property test of a semiconductor element is performed by bringing an inspection object (semiconductor wafer or semiconductor package) to an inspection device including a plurality of electrically conductive contact pins and bringing the electrically conductive contact pin into contact with a relevant external terminal (solder ball, bump, or the like) on the inspection object. An example of the inspection device may include a probe card or a test socket, but is not limited thereto.

The conventional test socket may include a pogo-type test socket and a rubber-type test socket.

An electrically conductive contact pin (hereinbelow, “pogo-type socket pin”) used in the pogo-type test socket includes a pin part and a barrel containing the pin part. The spring member is provided between plungers provided at opposite ends of the pin part, so that required contact pressure can be applied and shock at a contact location can be absorbed. In order to move the pin part in the barrel in a sliding manner, a gap should be provided between an outer surface of the pin part and an inner surface of the barrel. However, since the pogo-type socket pin including the barrel and the pin part which are separately formed and then coupled to each other is used, management of the gap cannot be precisely performed as the outer surface of the pint part and the inner surface of the barrel are spaced apart from each other more than necessary. Therefore, in a process in which electric signals are transmitted to the barrel through plungers at opposite ends, electrical signals are lost and distorted, and a problem of inconsistent contact stability occurs. Furthermore, the pin part includes a pointed tip to increase the contact effect with the external terminal. The pointed tip produces an impression or groove on the external terminal of the inspection object after inspection. Damage to the contact shape of the external terminal may cause errors in vision inspection and reduce the reliability of the external terminal in subsequent processes such as soldering.

Meanwhile, an electrically conductive contact pin (hereinbelow, “rubber-type socket pin”) used in the rubber-type test socket has a structure in which conducive micro balls are arranged inside a silicone rubber made of rubber. When an inspection object (for example, a semiconductor package) is placed and then the socket is closed so that stress is applied, as the gold-based conductive micro balls press each other strongly, conduction increases, and electrically connection is achieved. However, the rubber-type socket pin is problematic in that contact stability can only be ensured when pressed with excessive pressure.

Meanwhile, recently, with the advancement and high integration of semiconductor technology, narrower pitches of external terminals of the inspection object are progressing further. However, the conventional rubber-type socket pin is formed by preparing a molding material with conductive particles distributed within a fluid elastic material, inserting the molding material into a predetermined mold, and then arranging the conductive particles in a thickness direction by applying a magnetic field in the thickness direction. Therefore, when the gap between magnetic fields narrows, the conductive particles are irregularly oriented and a signal flows in a planar direction. Therefore, there is a limitation in responding to the narrow pitch technology trend with the existing rubber-type socket pin.

Furthermore, since the pogo-type socket pin is formed and used with the barrel and the pin part which are separately prepared and then coupled to each other, there is a problem in that the pogo-type socket pin is formed into a small size. Therefore, also, there is a limitation in responding to the narrow pitch technology trend with the existing pogo-type socket pin.

Therefore, there is a need to develop a new type of electrically conductive contact pin that can improve the inspection reliability of the inspection object in line with recent technological trends.

### DOCUMENTS OF RELATED ART

### Patent Documents

(Patent Document 1) Korean Patent No. 10-0659944

(Patent Document 2) Korean Patent No. 10-0952712

### SUMMARY OF THE INVENTION

### Technical Problem

Accordingly, the present disclosure has been made keeping in mind the above problems occurring in the related art, and an objective of the present disclosure is to provide an electrically conductive contact pin to improve the inspection reliability of an inspection object.

Another objective of the present disclosure is to provide an electrically conductive contact pin with an elastic part that is elastically deformed easily during an overdrive process when pressure is applied to the electrically conductive contact pin so that damage to an inspection object is prevented.

### Technical Solution

In order to solve the above problems and achieve the above objectives, according to the present disclosure, there is provided an electrically conductive contact pin including an elastic part, wherein the elastic part may include: a plurality of straight parts; a plurality of curved parts each connecting upper and lower adjacent straight parts to each other among the plurality of straight parts; and a slit part formed through a front surface and a second surface of each of the curved parts, wherein each of the curved parts may include a plurality of split beam parts formed of the slit part.

Beam widths of the plurality of split beam parts may be identical to each other.

Beam widths of the split beam parts may be larger in a direction from an inner part of each curved part to an outer part of each curved part.

The slit part may include a plurality of slit parts, wherein among the plurality of slit parts, a slit part provided at an inner part of each curved part may have a larger available space width than a slit part provided in an outer part of each curved part.

The split beam parts may have radii of curvature that may be larger in a direction from an inner part of each curved part to an outer part of each curved part.

The sum of beam widths of the split beam parts may be equal to the beam width of each of the straight parts.

Each of the split beam parts may have a bent portion having curvature, and a beam width of the bent portion may be smaller than a beam width of a surrounding portion.

A beam width of each of the straight parts may be less than a beam width of each of the curved parts.

Meanwhile, according to another aspect of the present disclosure, there is provided an electrically conductive contact pin including an elastic part, wherein the elastic part may include: a plurality of straight parts; a plurality of curved parts each connecting upper and lower adjacent straight parts to each other among the plurality of straight parts; and a stopper provided in at least one of the straight and curved parts and restricting an elastic deformation position of the elastic part.

Meanwhile, according to another aspect of the present disclosure, there is provided an electrically conductive contact pin including an elastic part, wherein the elastic part may include: a plurality of straight parts; a plurality of curved parts each connecting upper and lower adjacent straight parts to each other among the plurality of straight parts; and a groove part providing a cut portion on an inner surface of each of the curved parts and formed through a first surface and a second surface of each of the curved parts.

### Advantageous Effects

According to the present disclosure, the electrically conductive contact pin includes the elastic part having the slit part so that the elastic part is elastically deformed easily to prevent the inspection object from being damaged.

Furthermore, the straight part or the curved part includes the stopper to prevent excessive elastic deformation to prevent the elastic part from being damaged.

Furthermore, the curved part includes the groove part to facilitate elastic deformation so that damage to the elastic part is prevented.

### BRIEF DESCRIPTION OF DRAWINGS

FIG. 1 is a perspective view illustrating an electrically conductive contact pin according to the exemplary embodiment of the present disclosure, the electrically conductive contact pin having an elastic part according to an exemplary embodiment 1-1 of the present disclosure.

FIG. 2 is a front view illustrating the electrically conductive contact pin installed to an installation member, the electrically conductive contact pin according to the exemplary embodiment of the present disclosure having the elastic part according to the exemplary embodiment 1-1 of the present disclosure.

FIG. 3 is an enlarged view illustrating a part of the elastic part according to the exemplary embodiment 1-1 of the present disclosure.

FIG. 4 is an enlarged view illustrating a part of the elastic part according to an exemplary embodiment 1-2 of the present disclosure.

FIG. 5 is an enlarged view illustrating a part of the elastic part according to an exemplary embodiment 1-3 of the present disclosure.

FIG. 6 is an enlarged view illustrating a part of the elastic part according to an exemplary embodiment 1-4 of the present disclosure.

FIG. 7 is an enlarged view illustrating a part of the elastic part according to an exemplary embodiment 1-5 of the present disclosure.

FIG. 8 is an enlarged view illustrating a part of the elastic part according to an exemplary embodiment 1-6 of the present disclosure.

FIG. 9 is an enlarged view illustrating a part of the elastic part according to an exemplary embodiment 1-7 of the present disclosure.

FIG. 10 is an enlarged view illustrating a part of the elastic part according to an exemplary embodiment 1-8 of the present disclosure.

FIG. 11 is an enlarged view illustrating a part of the elastic part according to an exemplary embodiment 1-9 of the present disclosure.

FIG. 12 is an enlarged view illustrating a part of the elastic part according to an exemplary embodiment 1-10 of the present disclosure.

FIG. 13 is an enlarged view illustrating a part of the elastic part according to an exemplary embodiment 2 of the present disclosure.

FIG. 14 is an enlarged view illustrating a part of the elastic part according to the exemplary embodiment 3-1 of the present disclosure.

FIG. 15 is an enlarged view illustrating a part of the elastic part according to an exemplary embodiment 3-2 of the present disclosure.

FIG. 16 is an enlarged view illustrating a part of the elastic part according to the exemplary embodiment 3-3 of the present disclosure.

FIG. 17 is an enlarged view illustrating a part of the elastic part according to the exemplary embodiment 4-1 of the present disclosure.

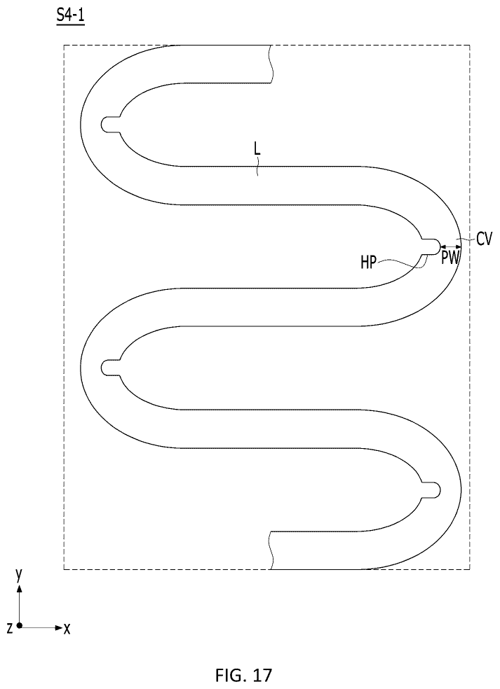

FIG. 18 is an enlarged view illustrating a part of the elastic part according to an exemplary embodiment 4-2 of the present disclosure.

### DESCRIPTION OF THE INVENTION

Hereinbelow, the following illustrates the principle of the present disclosure. Those skilled in the art will be able to embody the principle of the present disclosure and invent various apparatuses included in the spirit and the scope of the present disclosure, although not shown herein. Furthermore, all conditional terms and embodiments described herein are clearly intended to embody the principle of the present disclosure and invent various apparatuses included in the spirit and the scope of the present disclosure. Furthermore, all conditional terms and embodiments described herein are clearly intended for the purpose of understanding the concept of the present disclosure, and should be understood not to be limited to the specifically listed embodiments and states.

The above and other objectives, features and advantages of the present disclosure will be more clearly understood from the following detailed description taken in conjunction with the accompanying drawings.

The embodiments described herein will be described with reference to sectional views and/or perspective views, which are ideal drawings of the present disclosure. The thicknesses of films and regions illustrated in the drawings are exaggerated for an effective description of the technical sprit of the present disclosure. Variations from the shapes of the illustrations as a result, for example, of manufacturing techniques and/or tolerances, are to be expected. Therefore, the embodiments of the present disclosure are not limited to the specific forms shown in the drawings, but include the changes in the forms caused by manufacturing processes. The technical terms used in the specification are used to describe specific embodiments, and thus are not intended to limit the present disclosure. The singular expressions are intended to include the plural expressions unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Hereinafter, exemplary embodiments of the present disclosure will be described in detail with reference to the accompanying drawings. Hereinafter, in describing various embodiments, the same names and the same reference numbers will be used to refer to components that perform the same function even when the embodiments are different. Furthermore, configuration and operation already described in other embodiments will be omitted for convenience.

An electrically conductive contact pin according to the exemplary embodiment of the present disclosure (hereinbelow, which refers to the “electrically conductive contact pin 100 of the present disclosure”) is provided at a detecting device and transmits electrical signals while being in electrically and physically contact with an inspection object. The detecting device may be used in the semiconductor fabrication process, and for example, be a probe card or a test socket.

The installation member 1 may include a through hole 2 in which the electrically conductive contact pin 100 of the present disclosure is accommodated. Hereinbelow, as an example, the installation member 1 may be a guide plate GP including a guide hole GH.

The electrically conductive contact pin 100 of the present disclosure may be a probe pin provided in the probe card or a socket pin provided in a test socket. Hereinbelow, a socket pin will be illustrated as an example of the electrically conductive contact pin 100 of the present disclosure. However, the electrically conductive contact pin 100 of the present disclosure is not limited thereto and includes any kind of pins as long as it can determine whether an inspection object applying electricity is defective or not.

In the description hereinbelow, the width direction of the electrically conductive contact pin 100 of the present disclosure is the ±x direction in the drawings. The longitudinal direction of the electrically conductive contact pin 100 of the present disclosure is the ±y direction in the drawings. The thickness direction of the electrically conductive contact pin 100 of the present disclosure is the ±z direction in the drawings.

The electrically conductive contact pin 100 of the present disclosure has a full length size L in the longitudinal direction, a full width size W in the width direction (±x direction) perpendicular to the longitudinal direction (±y direction), and the full width size W in the width direction (±x direction) perpendicular to the longitudinal direction (±y direction).

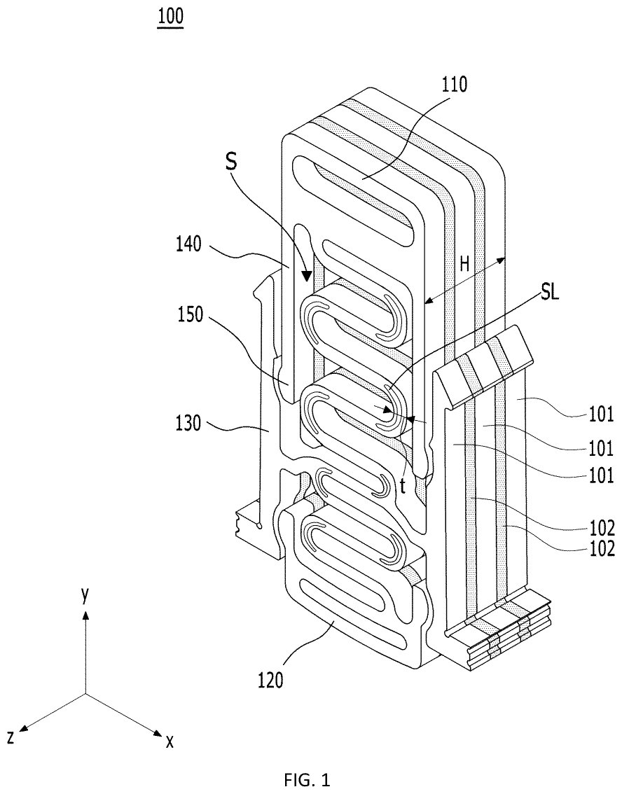

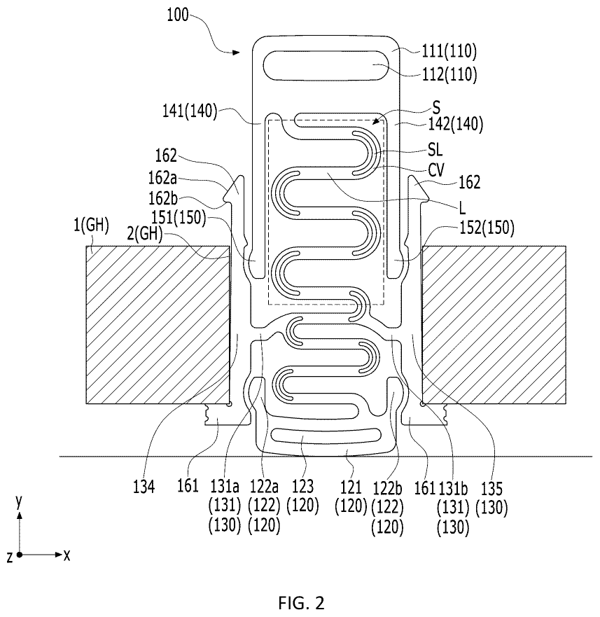

FIG. 1 is a perspective view illustrating the electrically conductive contact pin 100 according to an exemplary embodiment of the present disclosure. FIG. 2 is a front view illustrating the electrically conductive contact pin 100 according to the exemplary embodiment of the present disclosure. In the description referring to FIGS. 1 and 2, an “elastic part S” includes elastic parts S1-1, S1-2, S1-3, S1-4, S1-5, S1-6, S1-7, S1-8, S1-9, S1-10, S2, S3-1, S3-2, S3-3, S4-1, and S4-2 of embodiments 1-1 to 4-2.

Referring to FIGS. 1 and 2, the electrically conductive contact pin 100 of the present disclosure includes a first connection part 110 including a flange part 140 extending downward (−y direction) in the longitudinal direction (±y direction), a second connection part 120, a support part 130 extending in the longitudinal direction (±y direction), the elastic part S having a first end connected to the first connection part and a second end connected to the second connection part 120, and including a plurality of curved parts CV connecting a plurality of straight parts L and a plurality of straight parts L to each other, and elastically deformed in the longitudinal direction (±y direction), and the flange part 140 provided between the support part 130 and the elastic part S and extending in the longitudinal direction (±y direction).

The first connection part 110, the second connection part 120, the support part 130, the elastic part S, and the flange part 140 are provided in an integrated body. The first connection part 110, the second connection part 120, the support part 130, the elastic part S, and the flange part 140 are manufactured simultaneously in a plating process. The electrically conductive contact pin 100 of the present disclosure is formed using an anodic oxide mold with an internal space to fill a metal material into the internal space by electroplating. Accordingly, the first connection part 110, the second connection part 120, the support part 130, the elastic part S, and the flange part 140 are connected to each other in an integrated body. The existing electrically conductive contact pin is provided by separately manufacturing a barrel and a pin part and then assembling and coupling the barrel and the pin part to each other. However, the electrically conductive contact pin 100 of the present disclosure has a difference in configuration in the aspect that the first connection part 110, the second connection part 120, the support part 130, the elastic part S, and the flange part 140 are manufactured simultaneously in the plating process in an integrated body.

The electrically conductive contact pin 100 of the present disclosure includes an anodic oxide mold so that a full thickness size H thereof may have a range equal to or greater than 80 [symbol] and equal to or less than 160 [symbol] . Furthermore, in forming the internal space in the anodic oxide mold, since an anodic oxide film having high rigidity remains as a wall body, it is possible to manufacture the anodic oxide mold to have a line width t of a high aspect ratio.

In the anodic oxide mold used to manufacture the electrically conductive contact pin 100 of the present disclosure, the internal space is formed by etching the anodic oxide film that is already in a solid state. Therefore, precise patterning is possible, allowing the mold to be formed without steps, but to have a height equal to or higher than 80 [symbol] and equal to or lower than 160 [symbol] .

The electrically conductive contact pin 100 of the present disclosure has the line width t, and among line widths t, based on the smallest line width, an aspect ratio (H:t) of the full thickness size H and the line width t is a range equal to or greater than 13:1 and equal to or less than 80:1. At this point, among the line widths t, the smallest line width t may be equal to greater than 2 [symbol] and equal to or less than 6 [symbol] .

The electrically conductive contact pin 100 of the present disclosure is formed such that the line width t of a flat plate constituting the electrically conductive contact pin 100 is small and the full thickness size H of the flat plate is large. In other words, the full thickness size H is formed largely in proportion to the line width t the flat plate. Preferably, the line width t of the flat plate has a range equal to or greater than 2 [symbol] and equal to less than 15 [symbol] , and the full thickness size H has a range equal to or greater than 80 [symbol] and equal to or less than 160 [symbol] , but the full thickness size H and the line width t of the flat plate are provided in a range from 1:13 to 1:80. For example, the line width t of the flat plate is formed to be practically 4 [symbol] , and the full thickness size H thereof is formed to be 100 [symbol] , so that the line width t and the full thickness size H of the flat plate may have a ratio of 1:25.

The electrically conductive contact pin 100 of the present disclosure has an equal shape of each section in the thickness direction (±z direction). In other words, an equal shape on the x-y plane extends in the thickness direction (±z direction) to form the electrically conductive contact pin 100.

The electrically conductive contact pin 100 of the present disclosure is formed by stacking multiple metal layers in the thickness direction (±z direction). The multiple metal layers include a first metal layer 101 and a second metal layer 102.

The first metal layer 101 has relatively higher wear resistance than the second metal layer 102 and, preferably, may be formed of a metal selected from rhodium (Rd), platinum (Pt), iridium (Ir), palladium (Pd), nickel (Ni), manganese (Mn), tungsten (W), phosphorus (Ph), or an alloy thereof, or palladium-cobalt (PdCo) alloy, palladium-nickel (PdNi) alloy or nickel-phosphorus (NiPh) alloy, nickel-manganese (NiMn), nickel-cobalt(NiCo), or nickel-tungsten(NiW) alloy. The second metal layer 102 has relatively higher electric conductivity than the first metal layer 101 and, preferably, may be formed of a metal selected from copper (Cu), silver (Ag), gold (Au), or an alloy thereof. However, the metal layers are not limited thereto.

The first metal layer 101 is provided at each of the lower and upper surfaces in the thickness direction (±z direction) of the electrically conductive contact pin 100a, and the second metal layer 102 is provided between one first metal layer 101 and another first metal layer 101. For example, the electrically conductive contact pin 100a is provided such that the first metal layer 101, the second metal layer 102, and the first metal layer 101 are staked alternately in order in the thickness direction (±z direction), and the number of stacked layers may be equal to or greater than 3 layers.

Referring to FIG. 2, the first connection part 110 includes a contact part 111 that is brought into contact with the inspection object and a contact hollow part 112 formed in the contact part 111.

The contact part 111 is a portion to be brought into contact with a connection terminal of the inspection object. The contact part 111 is formed by extending in the width direction (±x direction). In the longitudinal direction (±y direction)m, a lower surface of the contact part 111 is connected to the elastic part S.

The contact part 111 includes the contact hollow part 112 formed through a first surface and a second surface of the contact part 111 in the thickness direction (±z direction). The contact hollow part 112 is provided at a central portion of the contact part 111. When the inspection object is tested, the upper surface of the contact part 111 is brought into contact with the connection terminal of the inspection object. At this point, the contact hollow part 112 is an empty space of which a left portion and a right portion are formed to be curved in the width direction (±x direction) so that the upper surface of the contact part 111 is easily deformed.

The first connection part 110 is connected to the elastic part S, and a contact pressure allows the first connection part 110 to be elastically movable in a vertical direction (±y direction) based on the longitudinal direction (±y direction). When the inspection object is tested, the connection terminal of the inspection object is brought into contact with the upper surface of the first connection part 110 and is lowered downward (−y direction) while gradually press-deforming the elastic part S connected to the first connection part 110.

The flange part 140 extends downward (−y direction) based on the longitudinal direction (±y direction) from the lower end surface of the first connection part 110. The flange part 140 includes a first flange part 141 at a first end portion of the contact part 111 and a second flange part 142 at a second end portion of the contact part 111 based on the width direction (±x direction), the first flange part 141 extending downward from the first end portion in the longitudinal direction (±y direction) and the second flange part 142 extending downward from the second end portion, and an anti-deformation part 150 formed at an end of the flange part 140.

The flange part 140 has a width directional (±x direction) size of a free end greater than a portion around the free end. Accordingly, an outer surface of the end of the flange part 140 is formed in a shape protruding convexly outward in the width direction (±x direction). As the end of the flange part 140 is formed in a convex shape, the end of the flange part 140 includes the anti-deformation part 150. Specifically, an end of the first flange part 141 includes a first anti-deformation part 151, and an end of the second flange part 142 includes a second anti-deformation part 152.

The flange part 140 is provided between the support part 130 and the elastic part S on the basis of the width direction (±x direction). In other words, the support part 130 is provided outside the flange part 140 and the elastic part S is provided inside the flange part 140.

While the elastic part S is not pressed, the flange part 140 is spaced apart from the support part 130.

The flange part 140 is located such that the anti-deformation part 150 is inserted into the support part 130 by a predetermined length based on the longitudinal direction (±y direction) of the support part 130 and corresponds to a middle portion of the support part 130. At this point, the support part 130 has a concave portion on an inner surface at a position corresponding to the anti-deformation part 150 so that the concave portion corresponds to the convex outer surface of the flange part 140. At least one of the first and second anti-deformation parts 151 and 152 prevents overbending of the elastic part S by being brought into contact with the concave portion of the inner surface of the support part 130 when eccentric pressure of the connection terminal is applied to the first connection part 110 due to alignment errors or manufacturing errors of the connection terminal. Since at least one of the first and second anti-deformation parts 151 and 152 is brought into contact with the support part 130 even when eccentric pressure is applied, it is possible for the electrically conductive contact pin 100 of the present disclosure to form a current path.

Meanwhile, when a non-eccentric even pressure of the connection terminal is applied to the first connection part 110, each of the first and second anti-deformation parts 151 and 152 is brought into contact with the concave portion on the corresponding position of the inner surface of the support part 130. Accordingly, the current path extending from the first connection part 110 to the support part 130 is formed.

The support part 130 extends in the longitudinal direction (±y direction) and is provided at an outer side in the width direction (±x direction) of the flange part 140 of the first connection part 110. While the elastic part S is not pressed, the support part 130 and the flange part 140 are spaced apart from each other.

The support part 130 includes a first support part 134 located at a first side of the first connection part 110 and a second support part 135 located at a second side of the first connection part 110. At this point, middle portions of the inner surfaces of the first and second support parts 134 and 135 are formed in concave portions, and the concave portions correspond to the first and second anti-deformation parts 151 and 152. A portion above each concave portion of the support part 130 includes a protruding portion extending a predetermined length inward in the width direction (±x direction). Accordingly, each concave portion is formed in a groove shape. While the elastic part S is not pressed, the groove-shaped concave portion has a bottom surface in the width direction (±x direction) that is located to be spaced apart from the anti-deformation part 150. In other words, while the elastic part S is not pressed, the anti-deformation part 150 is accommodated without contacting the bottom surface in the width direction(±x direction) of the groove-shaped concave portion.

The support part 130 includes a support extension part 131 below each concave portion corresponding to the anti-deformation part 150.

The support extension part 131 includes a first support extension part 131a extending inward in the width direction (±x direction) from the inner surface of the first support part 134 and a second support extension part 131b extending inward in the width direction (±x direction) from the inner surface of the second support part 135.

An end of the first support extension part 131a is connected to a first portion of the elastic part S, and an end of the second support extension part 131b is connected to a second portion of the elastic part S. Specifically, an end of the first support extension part 131a is connected to a curved part CV provided at a first portion in the width direction (±x direction) of a straight part L. An end of the second support extension part 131b is connected to a curved part CV provided at a second portion of a straight part L. Accordingly, the support part 130 and the elastic part S are formed integrally. The first and second support extension parts 131a and 131b are provided below the concave portions and located at an equal height in the longitudinal direction (±y direction) to each other.

When the first connection part 110 is moved downward (−y direction) due to pressure of the connection terminal, the first and second support extension parts 131a and 131b may provide the function to limit additional descent of the first and second anti-deformation parts 151 and 152.

The support part 130 includes a first locking part 161 on a first end portion (−y direction) in the longitudinal direction (±y direction). The first locking part 161 is provided at a first end portion of the support part 130 close to the second connection part 120. In other words, the first locking part 161 is provided at a lower end portion of the support part 130. The first locking part 161 has a shape protruding outward in the width direction (±x direction).

The support part 130 includes a second locking part 162 on a second end portion (+y direction) in the longitudinal direction (±y direction). The second locking part 162 includes an inclined part 162a and a protruding step 162b on an outer surface.

When the electrically conductive contact pin 100 of the present disclosure is inserted into the guide hole GH, the upper end of the support part 130 is press-deformed inward in the width direction (±x direction) to be inserted into a lower opening of the guide hole GH. Then, the electrically conductive contact pin 100 of the present disclosure is forcibly pushed into the guide hole GH being pressed in a direction from a lower portion (−y direction) to an upper portion (+y direction) in the longitudinal direction (±y direction). When the second locking part 162 passes through an upper opening of the guide hole GH, the upper end portion of the support part 130 including the second locking part 162 is restored while spreading outward in the width direction(±x direction) due to elastic restoring force of the support part 130. At this point, the upper surface of the first locking part 161 is supported by contacting the lower surface of the guide plate GP existing around the lower opening of the guide hole GH.

The support part 130 includes a concave portion on an inner surface of the lower end portion in the longitudinal direction (±y direction) where the first locking part 161 is provided. Previously, the concave portion corresponding to each of the first and second anti-deformation parts 151 and 152 is provided close to the upper end portion where the second locking part 162 is provided. The support part 130 includes a concave portion on the inner surface of the lower end portion, and the concave portion of the lower end portion corresponds to an end portion that is a free end of the second connection part 120.

The second connection part 120 is in contact with a pad of a circuit board.

The second connection part 120 includes a connect body part 121, connect extension parts 122 extending upward in the longitudinal direction (±y direction) on both portions of the width direction(±x direction) of the connect body part 121, and a connect hollow part 123 formed at a central portion of the connect body part 121.

The second connection part 120 has the connect body part 121 of which a lower end surface is formed convexly to have a predetermined curvature. The second connection part 120 is pressed while contacting the pad of the circuit board with the lower end surface of the connect body part 121.

The second connection part 120 includes the connect extension parts 122 extending upward in the longitudinal direction (±y direction) on both end portions in the width direction (±x direction) of the connect body part 121. The connect extension parts 122 include a first connect extension part 122a provided on a first end portion in the width direction(±x direction) of the connect body part 121 and extending upward (+y direction) in the longitudinal direction (±y direction), and a second connect extension part 122b provided on a second end portion in the width direction (±x direction) of the connect body part 121 and extending upward (+y direction) in the longitudinal direction (±y direction).

The first and second connect extension parts 122a and 122b are formed such that outer surfaces in the width direction (±x direction) are convex. Accordingly, the outer surface of the connect extension part 122 further protrudes outward in the width direction(±x direction) than the outer surface of the connect body part 121.

The first and second connect extension parts 122a and 122b are inserted by a predetermined length in the longitudinal direction (±y direction) to be located in the support part 130. The first and second connect extension parts 122a and 122b are located to correspond to the concave portions of the lower end portions of the support part 130 in the width direction (±x direction). When the elastic part S is not press-deformed, the first and second connect extension parts 122a and 122b and the concave portions of the lower end portions of the support part 130 are spaced apart from each other.

Meanwhile, when the second connection part 120 is brought into contact with the pad by pressure of the connection terminal, the elastic part S connected to the second connection part 120 is press-deformed in the longitudinal direction (±y direction). Accordingly, the first and second connect extension parts 122a and 122b are brought into contact with the inner surfaces of the support part 130. Specifically, the first and second connect extension parts 122a and 122b are brought into contact with the concave portions of the lower end portions of the support part 130.

When pressure of the connection terminal is applied to the electrically conductive contact pin 100 of the present disclosure, the elastic part S connected with the first connection part 110 is press-deformed, and when the second connection part 120 is brought into contact with the pad, the elastic part S connected to the second connection part 120 is press-deformed. At this point, at the upper end portion of the electrically conductive contact pin 100 of the present disclosure where the first connection part 110 is provided, the first and second anti-deformation parts 151 and 152 are brought into contact with the concave portions of the upper end portions of the support part 130. At the lower end portion of the electrically conductive contact pin 100 of the present disclosure where the second connection part 120 is provided, the first and second connect extension parts 122a and 122b are brought into contact with the concave portions of the lower end portions of the support part 130. Accordingly, the electrically conductive contact pin 100 of the present disclosure has the current path connecting the first connection part 110, the support part 130, and the second connection part 120 to each other.

The elastic part S is provided between the first connection part 110 and the second connection part 120 in the longitudinal direction (±y direction) and provided inside the first and second connection parts 110 and 120.

A first end of the elastic part S is connected to the first connection part 110, and a second end is connected to the second connection part 120, allowing the first and second connection parts 110 and 120 to be integrally connected to each other through the elastic part S.

The elastic part 150 has a shape formed by the flat plate with a practice width t repeatedly bent in an S shape, and the practice width t of the flat plate is constant throughout.

The elastic part S includes the plurality of straight parts L and the curved parts CV, each curved part CV connecting upper and lower adjacent straight parts L to each other. The elastic part S is formed of the plurality of straight parts L and the plurality of curved parts CV that are alternatively connected to each other. Each straight part L connects left and right curved parts CV adjacent in the width direction (±x direction). Each curved part CV connects upper and lower straight parts L adjacent to each other. Each curved part CV is provided in a circular arc shape.

The plurality of straight parts L is arranged at the center of the elastic part S, and the curved parts CV is arranged at the outside part of the elastic part S. Each straight part L is provided in parallel to the width direction(±x direction) so that deformation of each curved part CV depending on a contact pressure is easily performed.

Hereinbelow, various embodiments of the elastic part S provided in the electrically conductive contact pin 100 of the present disclosure will be described.

### Elastic Part S1-1 of Embodiment 1-1

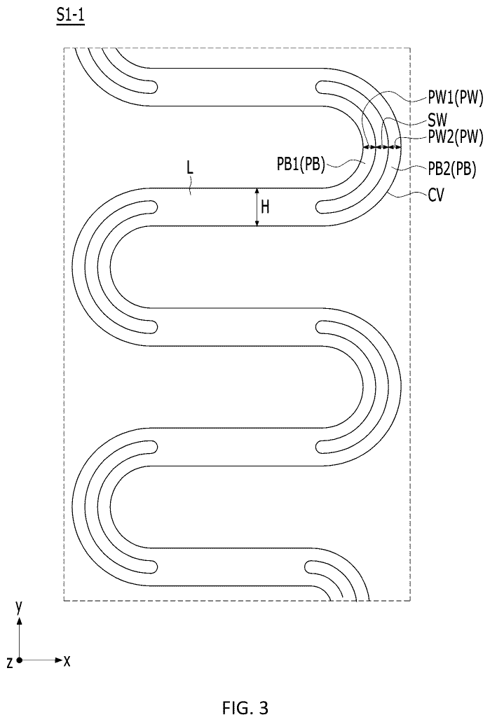

FIG. 2 is a front view illustrating the electrically conductive contact pin 100 including the elastic part of an exemplary embodiment 1-1 of the present disclosure (hereinbelow, which refers to the elastic part S1-1 of the embodiment 1-1). FIG. 3 is an enlarged view illustrating a part of the elastic part S1-1 of the embodiment 1-1.

The electrically conductive contact pin 100 of the present disclosure includes the elastic part S1-1 of the embodiment 1-1.

Referring to FIGS. 1 to 3, the elastic part S1-1 of the embodiment 1-1 includes the plurality of straight parts L, the plurality of curved parts CV, and slit parts SL formed through a first surface and a second surface of each of the curved parts CV.

The elastic part S1-1 of the embodiment 1-1 includes one slit part SL for one curved part CV. Each of the slit parts SL is formed through the first surface and the second surface of the curved parts CV in the thickness direction (the ±z direction).

Each slit part SL is formed in a shape having a curvature to correspond to each curved part CV of the circular arc shape having a curvature. Each slit part SL is provided at a central portion of each curved part CV in the width direction (±x direction). Accordingly, each curved part CV has portions divided by each slit part SL formed at the central portion.

Each curved part CV includes a plurality of split beam parts PB through the portions divided by each slit part SL.

The split beam parts PB includes a first split beam parts PB1 provided inside each slit part SL in the width direction(±x direction) and a second split beam parts PB2 provided outside each slit part SL. The plurality of split beam parts PB may have an equal beam width (or beam size) PW in the width direction(±x direction) or different beam widths. Hereinbelow, the beam width PW (beam size) of the split beam parts PB is a size of the split beam parts PB in the width direction (±x direction).

When the beam widths PW1 and PW2 of the first and second split beam parts PB1 and PB2 are equal to each other, the beam width PW1, PW2 of the first, second split beam parts PB1, PB2 and the beam width SW of each slit part SL in the width direction (±x direction) may be equal to each other.

When the beam widths PW1 and PW2 of the first and second split beam parts PB1 and PB2 are different from each other, preferably, the beam width PW1 of the first split beam parts PB1 provided inside each slit part SL and provided inside each curved part CV in the width direction (±x direction) may be formed smaller than the beam width PW2 of the second split beam parts PB2. With this structure, when the elastic part S1-1 of the embodiment 1-1 is elastically deformed due to pressure of the connection terminal, an inner portion of each curved part CV in the width direction (±x direction) is deformed easier than the outer portion thereof, allowing elastic deformation of the elastic part S1-1 of the embodiment 1-1 to be easily performed.

In the elastic part S1-1 of the embodiment 1-1, each slit part SL is not provided at the central portion of each curved part CV, but is provided to be biased inward of each curved part CV in the width direction (±x direction), allowing forming the beam widths PW1 and PW2 of the first and second split beam parts PB1 and PB2 different from each other. In this state, a spacing distance between the inner surface of each curved part CV and each slit part SL is smaller than a spacing distance between the outer surface of each curved part CV and each slit part SL. The spacing distance between the inner surface of each curved part CV and each slit part SL provides the beam width PW1 of the first split beam parts PB1, and the spacing distance between the outer surface of each curved part CV and each slit part SL provides the beam width PW2 of the second split beam parts PB2. Therefore, the beam width PW1 of the first split beam parts PB1 is provided smaller than the beam width PW2 of the second split beam parts PB2. Accordingly, the elastic part S1-1 of the embodiment 1-1 may have the split beam parts (the first split beam parts PB1) located at the inner portion of each curved part CV, with the relatively small beam width PW1.

The elastic part S1-1 of the embodiment 1-1 accommodates the elastically deformed shape of the first split beam parts PB1 through the slit parts SL when the split beam parts PB is elastically deformed due to pressure of the connection terminal.

Specifically, when the elastic part S1-1 of the embodiment 1-1 is elastically deformed, the first and second split beam parts PB1 and PB2 are pressed in the longitudinal direction (±y direction) due to pressure to be elastically deformed in a shape of which one portion protrudes outward in the width direction (±x direction). At this point, the elastic part S1-1 of the embodiment 1-1 receives elastic deformation of the first split beam parts PB1 in the width direction(±x direction) through each slit part SL that has a predetermined beam width SW and is formed between the first and second split beam parts PB1 and PB2.

Accordingly, when the elastic part S1-1 of the embodiment 1-1 is elastically deformed, according to elastic deformation in the width direction(±x direction), the elastic part S1-1 of the embodiment 1-1 may be elastically deformed without contact interference between the first split beam parts PB1 and the second split beam parts PB2.

The elastic part S1-1 of the embodiment 1-1 includes the slit parts SL to form the split beam parts PB to the curved parts CV. Therefore, the elastic part S1-1 of the embodiment 1-1 includes each curved part CV of which the width directional (±x direction) size is relatively smaller than a width directional (±x direction) size of a curved part CV without a slit part SL. The width directional (±x direction) size of each curved part CV is the sum of the beam widths PW1 and PW2 of the plurality of split beam parts (the first and second split beam parts PB1 and PB2).

An elastic part without the slit parts SL is formed to have the curved part CV that is formed in a single circular arc. In this case, when the elastic part is elastically deformed, the elastic part is not elastically deformed easily due to the curved part CV having relatively large width.

It may be considered that the width directional (±x direction) size of each curved part CV is provided to be small, but in this case, each curved part CV is formed in a single circular arc having a small width directional (±x direction) size so that the strength of the elastic part may be weak. Accordingly, a problem of a damage to the curved parts CV may occur during elastic deformation of the elastic part.

However, the elastic part S1-1 of the embodiment 1-1 includes each slit parts SL at the central portion of the curved part CV so as to have each curved part CV constituting the split beam parts (the first, second split beam parts PB1, PB2 having the beam width PW1, PW2 that is not relatively small or great compared to the beam width H of each straight part L. Accordingly, the elastic part S1-1 of embodiment 1-1 may secure more strength than a curved part CV formed in a single circular arc and having a relatively small width directional (±x direction) size, and be elastically deformed easier than a curved part CV having a relatively large width directional (±x direction) size.

For the elastic part S1-1 of the embodiment 1-1, when the slit parts SL allows each curved part CV to have the split beam parts PB having different beam widths PW1 and PW2, the split beam parts (the second split beam parts PB2) having the beam width PW2 relatively large is provided to secure the strength of the elastic part, and the split beam parts (the first split beam parts PB1) having the beam width PW1 relatively small is provided to enable the elastic part to be elastically deformed easily. Accordingly, the elastic part S1-1 of the embodiment 1-1 may be easily deformed by pressure to prevent the damage problem.

The electrically conductive contact pin 100 of the present disclosure has the line width t of a high aspect ratio and increases the full thickness size H compared to the line width t. In other words, it is possible to increase the full thickness size H compared to the line width t of the flat plate constituting the elastic part S. Accordingly, even when each slit part SL is formed to pass through the first surface and the second surface of each curved part CV of the elastic part S, the strength of the elastic part can be secured.

Specifically, the elastic part S has the line width t of a high aspect ratio, and increases the full thickness size H compared to the line width t. Therefore, even when the slit parts SL are formed in the elastic part S1-1 of the embodiment 1-1, it is possible to provide the beam width PW of a high aspect ratio to the elastic part S1-1 of the embodiment 1-1 and increase the full thickness size H compared to the beam width PW. As the elastic part S1-1 of the embodiment 1-1 has the beam width PW of a high aspect ratio, elastic deformation of the elastic part S1-1 may be easily performed by having the slit parts SL, and damage may be prevented by having the strength.

### Elastic Part S1-2 of Embodiment 1-2

Next, the elastic part according to an exemplary embodiment 1-2 of the present disclosure (hereinbelow, which refers to the elastic part S1-2 of the embodiment 1-2). In the description below, the elastic part S1-2 of the embodiment 1-2 will be described with a focus on characteristic components compared to the elastic part S1-1 of the embodiment 1-1, and descriptions of similar or identical components to the embodiment 1-1 will be omitted as much as possible.

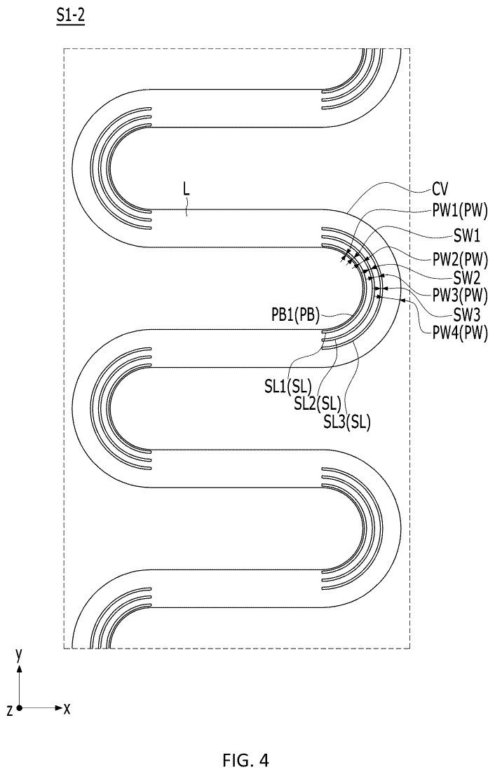

FIG. 4 is an enlarged view illustrating a part of the elastic part S1-2 of the embodiment 1-2.

The elastic part S1-2 of the embodiment 1-2 includes the plurality of slit parts SL including first to third slit parts SL1, SL2, and SL3 and the plurality of split beam parts PB formed by the first to third slit parts SL1, SL2, and SL3. The split beam parts PB may include first to fourth split beam parts PB1, PB2, PB3, and PB4.

The first to third slit parts SL1, SL2, and SL3 have the beam widths SW1, SW2, and SW3 equal to each other in the width direction (±x direction). Hereinbelow, the beam width SW of each slit part SL refers to a width directional size (±x direction) of the slit part SL. Each of the slit parts SL has an equal curvature.

The first to third slit parts SL1, SL2, and SL3 are formed at predetermined intervals in the width direction (±x direction.

The first to fourth split beam parts PB1, PB2, PB3, and PB4 are formed by the first to third slit parts SL1, SL2, and SL3 formed at the intervals therebetween.

Specifically, the first split beam parts PB1 is provided at the innermost portion of each curved part CV in the width direction (±x direction) and includes the inner surface of the curved part CV. The first split beam parts PB1 is provided by the first slit part SL1 that is formed to be spaced at the smallest interval outward in the width direction (±x direction) from the inner surface of each curved part CV. The first split beam parts PB1 has the relatively smallest beam width PW1.

The second split beam parts PB2 is formed by the second slit part SL2 that is formed to be spaced at a predetermined interval outward in the width direction (±x direction) from the first slit part SL1. The interval between the second slit part SL2 and the first slit part SL1 is larger than the interval between the inner surface of the curved part CV and the first slit part SL1. Therefore, the beam width PW2 of the second split beam parts PB2 is larger than the beam width PW1 of the first split beam parts PB1.

The third split beam parts PB3 is formed by the third slit part SL3 that is formed to be spaced at a predetermined interval outward in the width direction (±x direction) from the second slit part SL2. The interval between the third slit part SL3 and the second slit part SL2 is larger than the interval between the second slit part SL2 and the first slit part SL1. Therefore, the beam width PW3 of the third split beam parts PB3 is larger than the beam width PW2 of the second split beam parts PB2.

The fourth split beam parts PB4 is formed by an interval between the third slit part SL3 and the outer surface of the curved part CV. The interval between the third slit part SL3 and the outer surface of the curved part CV is larger than the interval between the third slit part SL3 and the second slit part SL2. Therefore, the beam width PW4 of the fourth split beam parts PB4 is larger than the beam width PW3 of the third split beam parts PB3.

The elastic part S1-2 of the embodiment 1-2 has the first to third slit parts SL1, SL2, and SL3 formed at intervals therebetween, the intervals being gradually larger in the direction from the inner portion of each curved part CV toward the outer portion of each curved part CV in the width direction (±x direction). In other words, the first to third slit parts SL1, SL2, and SL3 are formed in the width direction (±x direction) between the inner surface of each curved part CV and the outer surface of each curved part CV, and formed at intervals therebetween, the intervals being gradually larger in the direction from the inner surface of the curved part CV to the outer surface of the curved part CV.

Accordingly, the elastic part S1-2 of the embodiment 1-2 includes the plurality of split beam parts (specifically, the first to fourth split beam parts PB1, PB2, PB3, and PB4) of which the beam widths PW1, PW2, PW3, and PW4 are gradually larger in the direction from the inner portion of each curved part CV to the outer portion of the curved part CV in the width direction (±x direction).

The elastic part S1-2 of the embodiment 1-2 includes the first split beam parts PB1 having the smallest beam width PW1, the first split beam parts PB1 being located at the inner part of each curved part CV and including the inner surface of each curved part CV, and includes the second to fourth split beam parts PB2, PB3, and PB4 of which the beam width (PW2, PW3, PW4) are larger in order in the direction from the inner part of each curved part CV to the outer part of each curved part CV in the width direction (±x direction).

The elastic part S1-2 of the embodiment 1-2 includes the split beam parts (the first and second split beam parts PB1 and PB2 or the first to third split beam parts PB1, PB2, and PB3) having relatively small beam widths PW1 and P2 or PW1, PW2, and PW3 at the inner portion of each curved part CV. Therefore, when the elastic part S1-2 of the embodiment 1-2 is elastically deformed, the inner portion of the curved parts CV may be deformed more easily.

The elastic part S1-2 of the embodiment 1-2 includes the split beam parts (third and fourth split beam parts PB or the fourth split beam parts PB4) having relatively large beam widths (PW3 and PW4 or PW4) at the outer portion of each curved part CV. Therefore, the elastic part S1-2 of the embodiment 1-2 may secure the strength of the curved parts CV during elastic deformation thereof.

In other words, the elastic part S1-2 of the embodiment 1-2 includes the split beam parts (the first and second split beam parts PB1 and PB2 or the first to third split beam parts PB1, PB2, and PB3 having the relatively small beam widths PW1 and PW2 or PW1, PW2, and PW3 at the inner portion of each curved part CV where ease of elastic deformation is required, and includes the split beam parts (the third and fourth split beam parts PB or the fourth split beam parts PB4) having the relatively large beam widths PW3 and PW4 or PW4 at the outer portion of each curved part CV.

Therefore, when the elastic part S1-2 of the embodiment 1-2 is elastically deformed, the curved parts CV may be elastically deformed easily and damage thereto may be prevented at the same time.

### Elastic Part S1-3 of Embodiment 1-3

Next, the elastic part according to an exemplary embodiment 1-3 of the present disclosure (hereinbelow, which refers to the elastic part S1-3 of the embodiment 1-3). In the description below, the elastic part S1-3 of the embodiment 1-3 will be described with a focus on characteristic components compared to the elastic part S1-1, S1-2 of the embodiment 1-1, 1-2, and descriptions of similar or identical components will be omitted as much as possible.

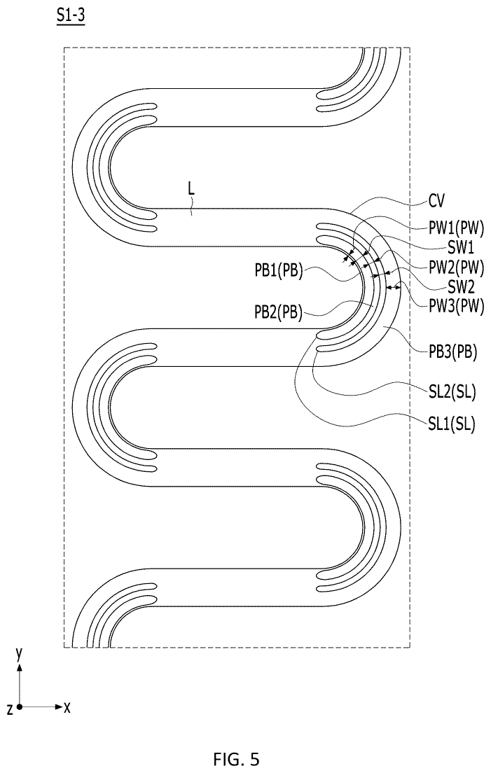

FIG. 5 is an enlarged view illustrating a part of the elastic part S1-3 of the embodiment 1-3.

The elastic part S1-3 of the embodiment 1-3 includes the first and second slit parts SL1 and SL2 and the first to third split beam parts PB1, PB2, and PB3.

The elastic part S1-3 of the embodiment 1-3 includes the first and second slit parts SL1 and SL2 of which the beam widths SW1 and SW2 are larger in the direction from the inner part of each curved part CV to the outer part of each curved part CV in the width direction (±x direction).

Specifically, the first slit part SL1 is provided at the inner part of each curved part CV and provided closest to the inner surface of each curved part CV, and the beam width SW1 of the first slit part SL1 is larger than the beam width SW2 of the second slit part SL2.

The second slit part SL2 is formed at an interval outward in the width direction (±x direction) from the first slit part SL1. At this point, the beam width SW2 of the second slit part SL2 is smaller than the beam width SW1 of the first slit part SL1. The elastic part S1-3 of the embodiment 1-3 includes the first and second slit parts SL1 and SL2 in which the beam width SW1 of the first slit part SL1 is formed larger than the beam width SW2 of the second slit part SL2.

The elastic part S1-3 of the embodiment 1-3 includes the slit part (the first slit part SL1) provided at the inner part of each curved part CV, of which the beam width SW1 is the largest. The beam width PW2 of the slit part (the second slit part SL2) provided at the outer part of each curved part CV is smaller than the beam width SW1 of the first slit part SL1. Therefore, among the multiple slit parts SL1 and SL2 of the elastic part S1-3 of the embodiment 1-3, the beam width SW2 of the second slit part SL2 is the smallest.

In other words, the elastic part S1-3 of the embodiment 1-3 includes the slit parts (the first and second slit parts SL1 and SL2) of which the beam widths SW1 and SW2 are smaller in the direction from the inner part of each curved part CV to the outer part of each curved part CV.

Therefore, in the elastic part S1-3 of the embodiment 1-3, an available space width of the first slit part SL1 formed by the beam width SW1 of the first slit part SL1 is larger than an available space width of the second slit part SL2 formed by the beam width SW2 of the second slit part SL2.

The first split beam parts PB1 is formed by the first slit part SL1 and has the beam width SW1 smaller than the beam width SW2 of the second split beam parts PB2. This structure is realized by forming the interval between the second slit part SL2 and the first slit part SL1 larger than the interval between the first slit part SL1 and the inner surface of each curved part CV.

Therefore, the beam width PW1 of the first split beam parts PB1 is smaller than the beam width PW2 of the second split beam parts PB2, and the beam width PW2 of the second split beam parts PB2 is larger than the beam width PW1 of the first split beam parts PB1.

The third split beam parts PB3 is formed by the interval between the outer surface of each curved part CV and the second slit part SL2, and the beam width PW3 of the third split beam parts PB3 is formed by the width of the interval between the outer surface of each curved part CV and the second slit part SL2.

The elastic part S1-3 of the embodiment 1-3 includes the third split beam parts PB3 provided at the outermost part of each curved part CV, and the beam width PW3 of the third split beam parts PB3 is the largest. Accordingly, the elastic part S1-3 of the embodiment 1-3 includes the split beam parts (the first to third split beam parts PB1, PB2, and PB3) of which the beam widths PW1, PW2, and PW3 are larger in the direction from the inner part of each curved part CV to the outer part.

The elastic part S1-3 of the embodiment 1-3 includes the first split beam parts PB1 located at the innermost portion of each curved part CV and the third split beam parts PB3 located at the outermost portion of each curved part CV, and the beam width PW1 of the first split beam parts PB1 is smaller than the beam width PW3 of the third split beam parts PB3. Therefore, the elastic part S1-3 of the embodiment 1-3 may be elastically deformed easily at the inner part of each curved part CV. Meanwhile, the elastic part S1-3 of the embodiment 1-3 includes the third split beam parts PB3 with the relatively largest beam width PW3 at the outer part of each curved part CV, thereby preventing the breakage problem that may occur during elastic deformation.

The first split beam parts PB1 of the elastic part S1-3 of the embodiment 1-3 has the smallest beam width PW1 and the first slit part SL1 provided around the first split beam parts PB1 has the largest available space width. When the elastic part S1-3 of the embodiment 1-3 is elastically deformed, while the first split beam parts PB1 is pressed in the longitudinal direction (±y direction), and a portion of the first split beam parts PB1 protrudes outward in the width direction (±x direction). At this point, the first slit part SL1 receives deformation in the width direction(±x direction) of the first split beam parts PB1.

For the elastic part S1-3 of the embodiment 1-3, the available space width of the first slit part SL1 is larger than the available space width of the second slit part SL2. Therefore, when the elastic part S1-3 of the embodiment 1-3 is elastically deformed, it is possible to prevent a problem of interference between the split beam parts occurring when the first split beam parts PB1 is brought into contact with the inner surface of the second split beam parts PB2.

### Elastic Part S1-4 of Embodiment 1-4

Next, the elastic part according to an exemplary embodiment 1-4 of the present disclosure (hereinbelow, which refers to the elastic part S1-4 of the embodiment 1-4). In the description below, the elastic part S1-4 of the embodiment 1-4 will be described with a focus on characteristic components compared to the elastic part S1-1, S1-2, S1-3 of the embodiment 1-1, 1-2, 1-3 and descriptions of similar or identical components to the elastic part S1-1, S1-2, S1-3 of the embodiment 1-1, 1-2, 1-3 will be omitted as much as possible.

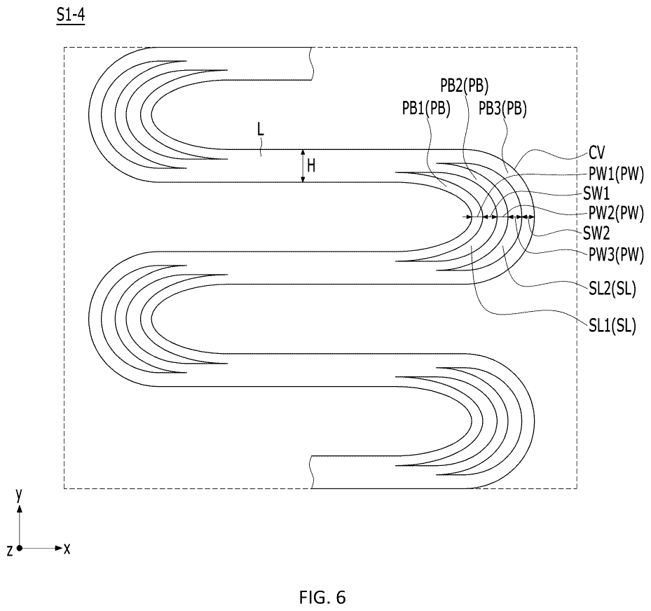

FIG. 6 is an enlarged view illustrating a part of the elastic part S1-4 of the embodiment 1-4.

The elastic part S1-4 of the embodiment 1-4 includes the first and second slit parts SL1 and SL2 and the first to third split beam parts PB1, PB2, and PB3 formed by the first and second slit parts SL1 and SL2.

The first and second slit parts SL1 and SL2 have the beam widths SW1 and SW2 equal to each other and are formed to spaced apart from each other. In this case, preferably, the beam widths PW1, PW2, and PW3 of the first to third split beam parts PB1, PB2, and PB3 are equal to each other.

The straight part L has a beam width H in the longitudinal direction (±y direction). Hereinbelow, the beam width H of the straight part L is a longitudinal directional (±y direction) size of the straight part L.

The elastic part S1-4 of the embodiment 1-4 is configured such that the sum of the beam widths PW1, PW2, and PW3 of the plurality of split beam parts (the first to third split beam parts PB1, PB2, and PB3) is equal to the beam width H of the straight part L. In other words, “the beam width H of the straight part L” is equal to the sum of the beam widths PW1, PW2, and PW3 of the first to third split beam parts PB1, PB2, and PB3.

Current flowing along the electrically conductive contact pin 100 of the present disclosure may flow along the elastic part S1-4 of the embodiment 1-4. At this point, the elastic part S1-4 of the embodiment 1-4 may form a flow of current without a bottleneck situation as the beam width H of the straight part L and the sum of the beam widths PW1, PW2, and PW3 of the first to third split beam parts PB1, PB2, and PB3 are equal to each other.

The elastic part S1-4 of the embodiment 1-4 is configured such that the first to third split beam parts PB1, PB2, and PB3 have different radii of curvature.

Specifically, in the elastic part S1-4 of the embodiment 1-4, the radii of curvature of the first to third split beam parts PB1, PB2, and PB3 are larger in the direction from the inner part of each curved part CV to the outer part of each curved part CV. In the direction from the inner part of each curved part CV to the outer part of each curved part CV, the radii of curvature are larger in order of the first split beam parts PB1, the second split beam parts PB2, and the third split beam parts PB3.

Accordingly, the first split beam parts PB1 provided at the innermost part of each curved part CV has the smallest radius of curvature among the first to third split beam parts PB1, PB2, and PB3. The third split beam parts PB3 provided at the outermost portion of each curved part CV has the largest radius of curvature among the first to third split beam parts PB1, PB2, and PB3.

When the pressure of the connection terminal is applied to the electrically conductive contact pin 100 of the present disclosure, the elastic part S1-4 of the embodiment 1-4 is elastically deformed. The first to third split beam parts PB1, PB2, and PB3 of the elastic part S1-4 of the embodiment 1-4 have different radii of curvature, and the first split beam parts PB1 provided at the innermost part of each curved part CV has the smallest radius of curvature. In the elastic part, elastic deformation is performed by the curved parts, and when elastic deformation is not performed easily at the inner portion of each curved part, the elastic part may be damaged and damage to the connection terminal may be caused. However, the elastic part S1-4 of the embodiment 1-4 includes the first split beam parts PB1 provided at the inner portion of each curved part CV, the first split beam parts PB1 realizing practically elastic deformation of the elastic part S1-4, of which the curvature radius thereof is the smallest compared to the second, third split beam parts PB. Accordingly, when the elastic part S1-4 of the embodiment 1-4 is elastically deformed, elastic deformation may be easily performed without damage to the elastic part S1-4 or the connection terminal, and the elastic part S1-4 may be easily restored when pressure is removed. Accordingly, the electrically conductive contact pin 100 of the present disclosure may improve the test efficiency for the inspection object.

### Elastic Part S1-5 of Embodiment 1-5

Next, the elastic part according to an exemplary embodiment 1-5 of the present disclosure (hereinbelow, which refers to the elastic part S1-5 of the embodiment 1-5). In the description below, the elastic part S1-5 of the embodiment 1-5 will be described with a focus on characteristic components compared to the elastic part S1-1, S1-2, S1-3, S1-4 of the embodiment 1-1, 1-2, 1-3, 1-4 and descriptions of similar or identical components will be omitted as much as possible.

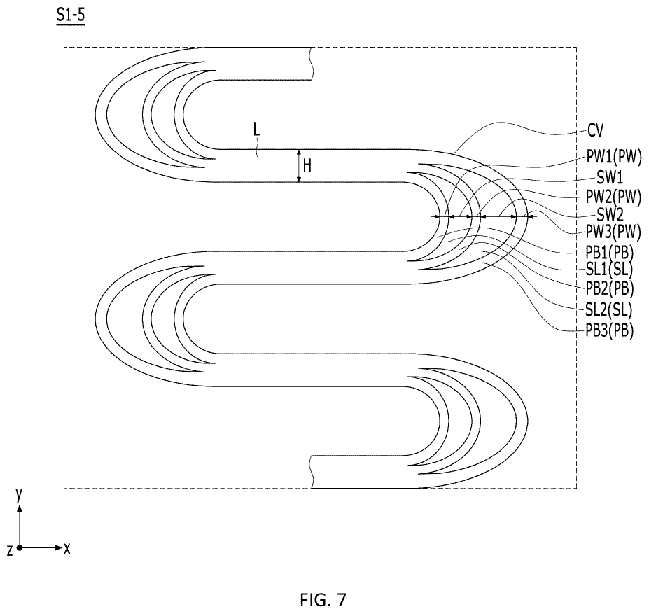

FIG. 7 is an enlarged view illustrating a part of the elastic part S1-5 of the embodiment 1-5.

The elastic part S1-5 of the embodiment 1-5 includes the first and second slit parts SL1 and SL2 and the first to third split beam parts PB1, PB2, and PB3 formed by the first and second slit parts SL1 and SL2.

In the elastic part S1-5 of the embodiment 1-5, the radii of curvature of the first to third split beam parts PB1, PB2, and PB3 are smaller in the direction from the inner part of each curved part CV to the outer part of each curved part CV. In other words, in the direction from the inner part of each curved part CV to the outer part of each curved part CV, the radii of curvature are smaller in order of the first split beam parts PB1, the second split beam parts PB2, and the third split beam parts PB3.

Accordingly, the beam widths SW1 and SW of the first slit part SL1 and the second slit part SL2, i.e., the available space width, are larger in the direction from the inner part of each curved part CV to the outer part of each curved part CV.

The beam widths PW1, PW2, and PW3 of the first to third split beam parts PB1, PB2, and PB3 may be equal to each other. Preferably, in the elastic part S1-5 of the embodiment 1-5, the straight part L and the first to third split beam parts PB1, PB2, and PB3 are provided such that the beam width H of the straight part L and the sum of the beam widths PW1, PW2, and PW3 of the first to third split beam parts PB1, PB2, and PB3 are equal to each other.

More specifically, the beam width H of the straight part L and the sum of the beam widths PW1, PW2, and PW3 at the central portions in the longitudinal direction (±y direction) of the first to third split beam parts PB1, PB2, and PB3 are equal to each other.

Accordingly, when current flows along the elastic part S1-5 of the embodiment 1-5, a flow of current to prevent a bottleneck situation may occur.

For the elastic part S1-5 of the embodiment 1-5, the beam widths SW1 and SW2 and the available space width of the plurality of slit parts SL are larger in the direction from the inner part of each curved part CV to the outer part of each curved part CV, so it is advantageous to prevent interference between the first and second split beam parts PB1 and PB2 during elastic deformation.

Specifically, the first slit part SL1 provided around the first split beam parts PB1 has a relatively large available space width due to a relatively large curvature radius of the first split beam parts PB1. Therefore, when the first split beam parts PB1 is elastically deformed in the longitudinal direction (±y direction) due to pressure and one portion of the first split beam parts PB1 protrudes in the width direction (±x direction), the protruding portion of the first split beam parts PB1 may be comfortably accommodated in the first slit part SL1. Accordingly, it is possible to prevent interference occurring due to contact between the second split beam parts PB2 provided at the outer surrounding portion in the width direction (±x direction) and the protruding portion of the first split beam parts PB1 protruding due to elastic deformation and accommodated in the first slit part SL1.

### Elastic Part S1-6 of Embodiment 1-6

Next, the elastic part according to an exemplary embodiment 1-6 of the present disclosure (hereinbelow, which refers to the elastic part S1-6 of the embodiment 1-6). In the description below, the elastic part S1-5 of the embodiment 1-5 will be described with a focus on characteristic components compared to the elastic part S1-1, S1-2, S1-3, S1-4, S1-5 of the embodiment 1-1, 1-2, 1-3, 1-4, 1-5 and descriptions of similar or identical components will be omitted as much as possible.

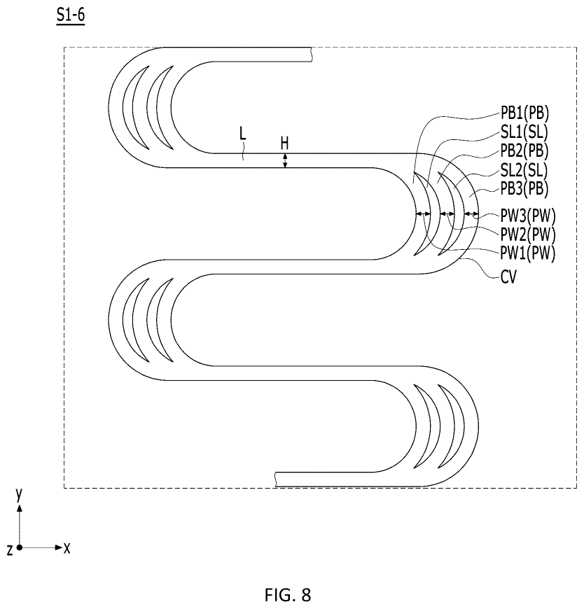

FIG. 8 is an enlarged view illustrating a part of the elastic part S1-6 of the embodiment 1-6.

The elastic part S1-6 of the embodiment 1-6 includes the first and second slit parts SL1 and SL2 and the first to third split beam parts PB1, PB2, and PB3 formed by the first and second slit parts SL1 and SL2.

The elastic part S1-6 of the embodiment 1-6 is configured such that the first to third split beam parts PB1, PB2, and PB3 have an equal radius of curvature.

The beam widths PW1, PW2, and PW3 of the first to third split beam parts PB1, PB2, and PB3 may be equal to each other. At this point, the elastic part S1-6 of the embodiment 1-6 is provided such that the beam width H of each straight part L and each of the beam widths PW1, PW2, and PW3 of the first to third split beam parts PB1, PB2, and PB3 are equal to each other.

Specifically, the beam width PW1 at the middle portion of the first split beam parts PB1 in the longitudinal direction (±y direction) is equal to the beam width H of each straight part L, the beam width PW2 at the middle portion of the second split beam parts PB2 in the longitudinal direction (±y direction) is equal to the beam width H of each straight part L, and the beam width PW3 at the middle portion of the third split beam parts PB3 in the longitudinal direction (±y direction) is equal to the beam width H of each straight part L.

The elastic part S1-6 of the embodiment 1-6 is provided to form the beam width H of each straight part L equal to each of the beam widths PW1, PW2, and PW3 of the split beam parts (PB1, PB2, PB3), so that the beam width H of each straight part L is relatively smaller than the entire beam width (specifically, the sum of the beam widths PW1, PW2, and PW3 of the first to third split beam parts PB1, PB2, and PB3) of each curved part CV. Accordingly, when the elastic part S1-6 of the embodiment 1-6 is elastically deformed, it is possible to induce the plurality of straight parts L to be deformed more easily so that there is an advantage in an aspect of elastic deformation efficiency of the elastic part S1-6 of the embodiment 1-6.

### Elastic Part S1-7 of Embodiment 1-7

Next, the elastic part according to an exemplary embodiment 1-7 of the present disclosure (hereinbelow, which refers to the elastic part S1-7 of the embodiment 1-7). In the description below, the elastic part S1-7 of the embodiment 1-7 will be described with a focus on characteristic components compared to the elastic part S1-1, S1-2, S1-3, S1-4, S1-5, S1-6 of the embodiment 1-1, 1-2, 1-3, 1-4, 1-5, 1-6 and descriptions of similar or identical components will be omitted as much as possible.

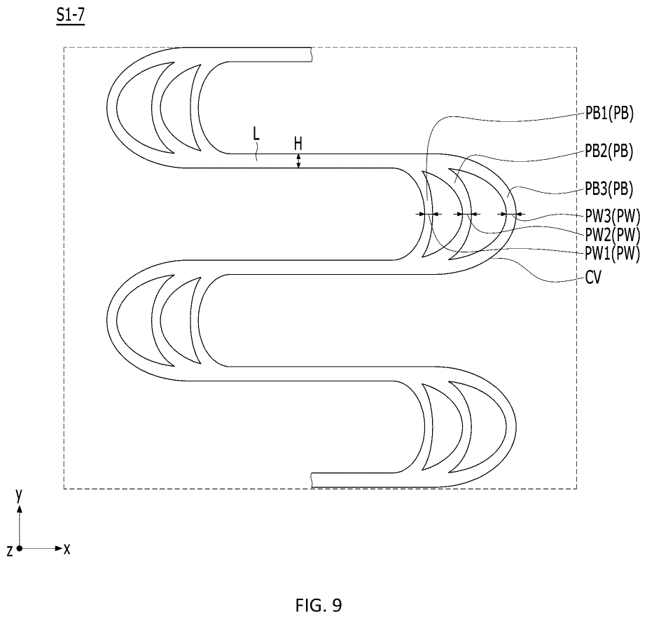

FIG. 9 is an enlarged view illustrating a part of the elastic part S1-7 of the embodiment 1-7.

The elastic part S1-7 of the embodiment 1-7 includes the first and second slit parts SL1 and SL2 and the first to third split beam parts PB1, PB2, and PB3 formed by the first and second slit parts SL1 and SL2.

In the elastic part S1-4 of the embodiment 1-4, the radii of curvature of the first to third split beam parts PB1, PB2, and PB3 are smaller in the direction from the inner part of each curved part CV to the outer part of each curved part CV. Specifically, in the direction from the inner part of each curved part CV to the outer part of each curved part CV, the radii of curvature are smaller in order of the first split beam parts PB1, the second split beam parts PB2, and the third split beam parts PB3. Accordingly, the elastic part S1-7 of the embodiment 1-7 includes the first and second slit parts SL1 and SL2 such that the available space widths are larger in the direction from the inner part of each curved part CV to the outer part of each curved part CV. Accordingly, the elastic part S1-7 of the embodiment 1-7 is advantageous to prevent the first and second split beam parts PB1 and PB2 from interfering with each other during elastic deformation.

The elastic part S1-7 of the embodiment 1-7 is provided such that the beam widths PW1, PW2, and PW3 at a middle portion in the longitudinal direction (±y direction) of the first to third split beam parts PB1, PB2, and PB3 are equal to the beam width H of each straight part L. Accordingly, when the elastic part S1-7 of the embodiment 1-7 is elastically deformed, it is possible to induce predetermined elastic deformation of the plurality of straight parts L.

### Elastic Part S1-8 of Embodiment 1-8

Next, the elastic part according to an exemplary embodiment 1-8 of the present disclosure (hereinbelow, which refers to the elastic part S1-8 of the embodiment 1-8). In the description below, the elastic part S1-8 of the embodiment 1-8 will be described with a focus on characteristic components compared to the elastic part S1-1, S1-2, S1-3, S1-4, S1-5, S1-6, S1-7 of the embodiment 1-1, 1-2, 1-3, 1-4, 1-5, 1-6, 1-7 and descriptions of similar or identical components will be omitted as much as possible.

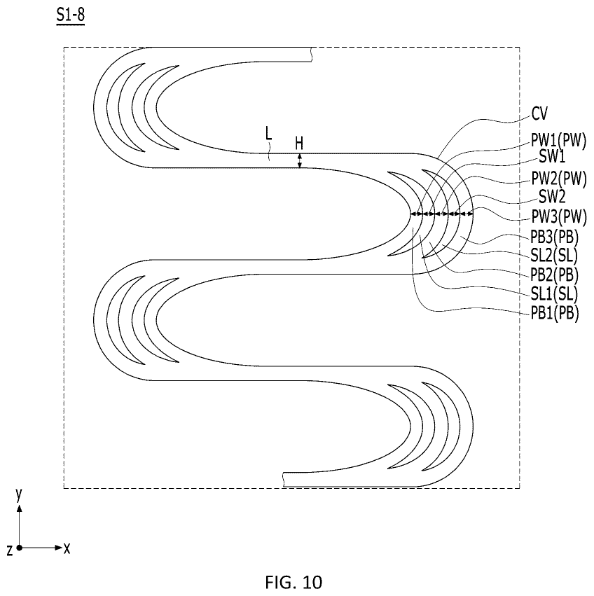

FIG. 10 is an enlarged view illustrating a part of the elastic part S1-8 of the embodiment 1-8.

The elastic part S1-8 of the embodiment 1-8 includes the first and second slit parts SL1 and SL2 and the first to third split beam parts PB1, PB2, and PB3 formed by the first and second slit parts SL1 and SL2.

The elastic part S1-8 of the embodiment 1-8 includes the first and second slit parts SL1 and SL2 and the first to third split beam parts PB1, PB2, and PB3 formed by the first and second slit parts SL1 and SL2.

In the elastic part S1-8 of the embodiment 1-8, the radii of curvature of the first to third split beam parts PB1, PB2, and PB3 are larger in the direction from the inner part of each curved part CV to the outer part of each curved part CV. Specifically, in the direction from the inner part of each curved part CV to the outer part of each curved part CV, the radii of curvature are larger in order of the first split beam parts PB1, the second split beam parts PB2, and the third split beam parts PB3.

Accordingly, the elastic part S1-8 of the embodiment 1-8 may be elastically deformed easily at the inner portion of each curved part CV.

The elastic part S1-8 of the embodiment 1-8 is provided such that the beam widths PW1, PW2, and PW3 of the first to third split beam parts PB1, PB2, and PB3 are equal to the beam width H of each straight part L. Accordingly, when the elastic part S1-8 of the embodiment 1-8 is elastically deformed, it is possible to induce predetermined elastic deformation of the plurality of straight parts L.

### Elastic Part S1-9 of Embodiment 1-9

Next, the elastic part according to an exemplary embodiment 1-9 of the present disclosure (hereinbelow, which refers to the elastic part S1-9 of the embodiment 1-9). In the description below, the elastic part S1-9 of the embodiment 1-9 will be described with a focus on characteristic components compared to the elastic part S1-1, S1-2, S1-3, S1-4, S1-5, S1-6, S1-7, S1-8 of the embodiment 1-1, 1-2, 1-3, 1-4, 1-5, 1-6, 1-7, 1-8 and descriptions of similar or identical components will be omitted as much as possible.

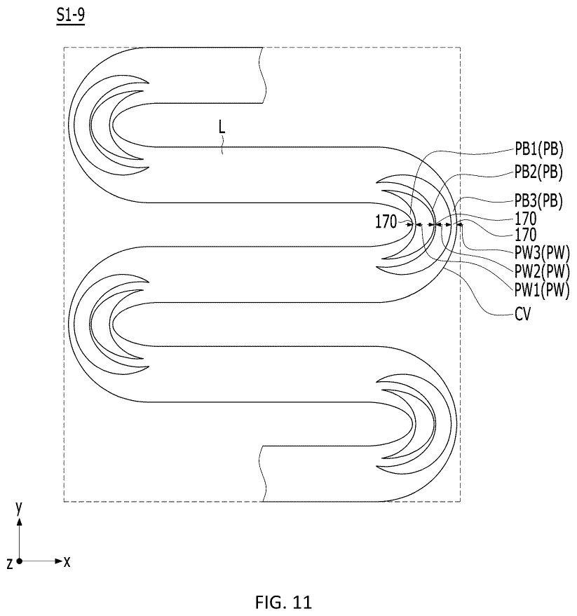

FIG. 11 is an enlarged view illustrating a part of the elastic part S1-9 of the embodiment 1-9.

The elastic part S1-9 of the embodiment 1-9 includes the first and second slit parts SL1 and SL2, and the plurality of split beam parts PB including the first to third split beam parts PB1, PB2, and PB3 formed by the first and second slit parts SL1 and SL2.

Each split beam parts PB includes a bent portion 170 having a curvature to form a radius of curvature of each split beam parts PB. The bent portion 170 is provided at a middle portion of each split beam parts PB in the longitudinal direction (±y direction) so that a horizontal center line thereof matches with a horizontal center line of each split beam parts PB. The beam width PW of the bent portion 170 provides the beam width PW in the width direction (±x direction) at the middle portion of each split beam parts PB in the longitudinal direction (±y direction).

The bent portion 170 of each split beam parts PB has a width directional (±x direction) size smaller than the surrounding portions (specifically, with respect to the upper and lower adjacent straight parts L, a portion connected to one end of the upper straight part L provided above the bent portion 170, in the longitudinal direction (±y direction), and a portion connected to one end of the lower straight part L).

Therefore, the split beam parts PB has the smallest beam width PW at the middle portion in the longitudinal direction (±y direction).

More specifically, each of the first to third split beam parts PB1, PB2, and PB3 has the smallest beam width PW1, PW2, PW3 at the middle portion in comparison to the beam widths PW of the upper and lower portions in the longitudinal direction (±y direction).

The upper surrounding portion of the first split beam parts PB1 above the bent portion 170 is connected to one end of the upper straight part L among the straight parts L vertically adjacent to each other. Therefore, the beam width PW1 at the upper surrounding portion may be measured as a longitudinal directional (±y direction) size and compared to the beam width PW1 at the middle portion of the split beam parts PB where the bent portion 170 is provided. Furthermore, the lower surrounding portion below the bent portion 170 is connected to one end of the upper straight part L among the straight parts L vertically adjacent to each other. Therefore, the beam width PW1 at the lower surrounding portion may be measured as a longitudinal directional (±y direction) size and compared to the beam width PW1 at the middle portion of the split beam parts PB where the bent portion 170 is provided. The beam width PW2, PW3 at the middle portion of the second, third split beam parts PB is equivalent thereto, and the detailed description thereof will be omitted.

The elastic part S1-9 of the embodiment 1-9 includes the split beam parts PB having a smaller beam width PW at the middle portion than the surrounding portions, allowing elastic deformation to be easily performed.

### Elastic Part S1-10 of Embodiment 1-10

Next, the elastic part according to an exemplary embodiment 1-10 of the present disclosure (hereinbelow, which refers to the elastic part S1-10 of the embodiment 1-10). In the description below, the elastic part S1-10 of the embodiment 1-10 will be described with a focus on characteristic components compared to the elastic part S1-1, S1-2, S1-3, S1-4, S1-5, S1-6, S1-7, S1-8, S1-9 of the embodiment 1-1, 1-2, 1-3, 1-4, 1-5, 1-6, 1-7, 1-8, 1-9, and descriptions of similar or identical components will be omitted as much as possible.

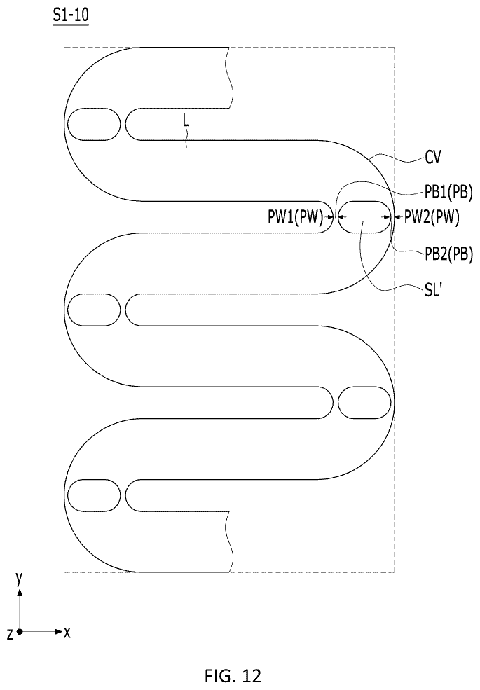

FIG. 12 is an enlarged view illustrating a part of the elastic part S1-10 of the embodiment 1-10.

The elastic part S1-10 of the embodiment 1-10 includes a slit part SL′ of which the width directional (±x direction) size is larger than the longitudinal directional (±y direction) size, and the slit part SL′ has an oval section of which both portions in the width direction(±x direction) have curvature. The oval slit part SL′ is provided at a central portion of each curved part CV and formed through the first surface and the second surface of each curved part CV.

The elastic part S1-10 of the embodiment 1-10 includes the first split beam parts PB1 at a first portion in the width direction(±x direction) of the oval slit part SL′, and the second split beam parts PB2 at a second portion thereof.

In the elastic part S1-10 of the embodiment 1-10, since the oval slit part SL′ has a relatively large width directional (±x direction) size, the beam width PW1 of the first split beam parts PB1 and the beam width PW2 of the second split beam parts PB2 are formed relatively small. Accordingly, the entire elastic deformation of the elastic part S1-10 of the embodiment 1-10 can be easily performed as the first and second split beam parts PB1 and PB2 are easily elastically deformed.

### Elastic Part S2 of Embodiment 2

Next, the elastic part according to an exemplary embodiment 2 of the present disclosure (hereinbelow, which refers to the elastic part S2 of the embodiment 2). In the description below, the elastic part S2 of the embodiment 2 will be described with a focus on characteristic components compared to the embodiment 1-1 to 1-10 (S1-1, S1-2, S1-3, S1-4, S1-5, S1-6, S1-7, S1-8, S1-9, S1-10) and descriptions of similar or identical components will be omitted as much as possible.

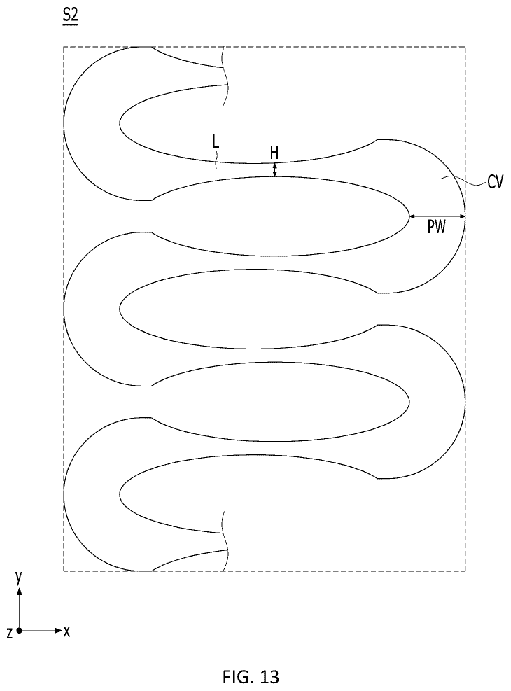

FIG. 13 is an enlarged view illustrating a part of the elastic part S2 of the embodiment 2.

The elastic part S2 of the embodiment 2 includes the plurality of straight parts L and the curved parts CV, each curved part CV connecting upper and lower adjacent straight parts L to each other. In FIG. 13, the elastic part S2 of the embodiment 2 is illustrated as a shape without the slit part SL, but each curved part CV may include the slit part SL and the split beam parts PB.

Each straight part L may be formed in a curved surface of which an upper surface and a lower surface in the longitudinal direction (±y direction) have curvature. Accordingly, each straight part L of the elastic part S2 of the embodiment 2 has the beam width H in the longitudinal direction (±y direction) that is gradually smaller in a direction from an outer portion to a middle portion in the width direction(±x direction) in comparison to each straight part with flat upper and lower surfaces. Each straight part L of the elastic part S2 of the embodiment 2 is provided such that the beam width H at the middle portion of each straight part L is smaller than the beam width H at the outer portion of each straight part L.

For the elastic part S2 of the embodiment 2, each of the plurality of straight parts L has a small beam width H in the longitudinal direction (±y direction) at the middle portion, which may induce elastic deformation of each straight part L during elastic deformation of the elastic part S2 of the embodiment 2.

The elastic part S2 of the embodiment 2 is configured to compare the beam width PW in the width direction (±x direction) of each curved part CV and the beam width H in the longitudinal direction (±y direction) of each straight part L to have the beam width H of each straight part L smaller than the beam width PW of each curved part CV. This may induce elastic deformation of the plurality of straight parts L along with elastic deformation of each curved part CV.

### Elastic Part S3-1 of Embodiment 3-1

Next, the elastic part according to an exemplary embodiment 3-1 of the present disclosure (hereinbelow, which refers to the elastic part S3-1 of the embodiment 3-1). In the description below, the elastic part S3-1 of the embodiment 3-1 will be described with a focus on characteristic components compared to the embodiment 1-1 to 2 (S1-1, S1-2, S1-3, S1-4, S1-5, S1-6, S1-7, S1-8, S1-9, S1-1 , S2) and descriptions of similar or identical components will be omitted as much as possible.

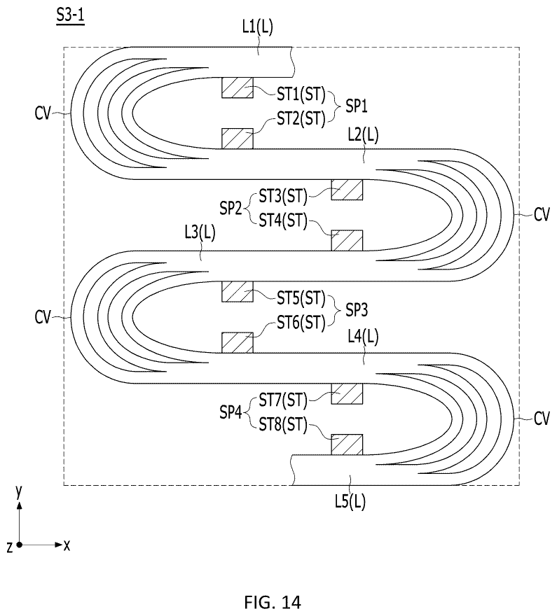

FIG. 14 is an enlarged view illustrating a part of the elastic part S3-1 of the embodiment 3-1.

The elastic part S3-1 of the embodiment 3-1 the first and second slit parts SL1 and SL2, the first to third split beam parts PB1, PB2, and PB3 formed by the first and second slit parts SL1 and SL2, and a stopper ST provided on each of the upper and lower adjacent straight parts L.

The elastic part S3-1 of the embodiment 3-1 has the equal shape to the elastic part S1-4 of the embodiment 1-4 and additionally include the stopper ST. Therefore, detailed descriptions of the straight parts L, the first and second slit parts SL1 and SL2, and the first to third split beam parts PB1, PB2, and PB3 provided in the elastic part S3-1 of the embodiment 3-1 are omitted.

The stopper ST includes at least one stopper ST. The stopper ST is provided on one surface of each straight part L.

The elastic part S3-1 of the embodiment 3-1 includes a plurality of stoppers ST. The elastic part S3-1 of the embodiment 3-1 includes first to eighth stoppers ST1, ST2, ST3, ST4, ST5, ST6, ST7, and ST8.

The elastic part S3-1 of the embodiment 3-1 includes the stoppers ST each provided on one surface of the first, second straight part L1, L2 adjacent in the vertical direction (±y direction). Specifically, each of the stoppers ST is provided on opposing surfaces of the vertically adjacent straight parts L. In FIG. 14, a stopper ST1 is provided on a lower surface of a first straight part L1 provided at the uppermost portion in the longitudinal direction (±y direction). A second stopper ST2 is provided on a second straight part L2 vertically opposite to the first straight part L1 and adjacent thereto.

The lower surface of the first straight part L1 and the upper surface of the second straight part L2 face each other. The elastic part S3-1 of the embodiment 3-1 includes the stoppers ST provided on the opposing surfaces of the first and second straight parts L1 and L2 adjacent in the vertical direction (±y direction). At this point, the stoppers ST are provided at positions corresponding to each other in the longitudinal direction (±x direction) to be brought into contact with each other during elastic deformation of the elastic part S3-1 of the embodiment 3-1.

The elastic part S3-1 of the embodiment 3-1 includes a first stopper unit SP1 consisting of the first and second stoppers ST1 and ST2 between the first and second straight parts L1 and L2.

The elastic part S3-1 of the embodiment 3-1 includes the stoppers ST each provided on one surface of the second, third straight part L2, L3 adjacent in the vertical direction (±y direction). The second stopper ST2 is provided on a first surface (upper surface) of the second straight part L2, the surface opposing the lower surface of the first straight part L1. Therefore, the second straight part L2 includes the second stopper ST2 on the upper surface opposing the lower surface of the first straight part L1, and includes a third stopper ST3 on a lower surface (second surface) opposing the upper surface of a third straight part L3. The second and third stoppers ST2 and ST3 are provided to facing each other at opposite positions in the width direction(±x direction) without overlapping when projecting second and third stoppers ST2 and ST3 in opposite directions in the longitudinal direction (±y direction).

A fourth stopper ST4 is provided on the upper surface of the third straight part L3 opposing the lower surface of the second straight part L2.

The third and fourth stoppers ST3 and ST4 are provided at the corresponding positions and brought into contact with each other during elastic deformation of the embodiment 3-1. The elastic part S3-1 of the embodiment 3-1 includes a second stopper unit SP2 between the second and third stoppers ST2 and ST3.

The first stopper unit SP1 and the second stopper unit SP2 are provided at positions not corresponding to each other in the longitudinal direction (±y direction). Specifically, the first stopper unit SP1 is provided at positions close to a first portion of the curved part CV connecting the first and second straight parts L1 and L2 to each other. The second stopper unit SP2 is provided at positions close to a second portion of curved part CV connecting the second and third straight parts L2 and L3 to each other. Accordingly, the first and second stopper units SP1 and SP2 are provided at opposite sides in the width direction (±x direction). Therefore, the first and second stopper units SP1 and SP2 do not overlap each other when projecting them in opposite directions in the longitudinal direction (±y direction).

A fifth stopper unit SP5 is provided at a second surface (lower surface) of the third straight part L3 of which the upper surface includes the fourth stopper ST4. Therefore, the third straight part L3 includes the fourth stopper ST4 on the upper surface and the fifth stopper ST5 on the lower surface. The fourth and fifth stoppers ST4 and ST5 are provided to facing each other at opposite positions in the width direction(±x direction) without overlapping when projecting the fourth and fifth stoppers ST4 and ST5 in opposite directions in the longitudinal direction (±y direction).

A sixth stopper ST6 is provided on an upper surface of a fourth straight part L4, opposing the lower surface of the third straight part L3.

The fifth and sixth stoppers ST5 and ST6 are provided at the corresponding positions and brought into contact with each other during elastic deformation of the embodiment 3-1. The elastic part S3-1 of the embodiment 3-1 includes a third stopper unit SP3 consisting of the fifth and sixth stoppers ST5 and ST6 between the third and fourth straight parts L3 and L4.

The second stopper unit SP2 and the third stopper unit SP3 are provided at positions not corresponding to each other in the longitudinal direction (±y direction). Specifically, the second stopper unit SP2 is provided at positions close to a second portion of the curved part CV connecting the first and second straight parts L1 and L2 to each other. The third stopper unit SP3 is provided at positions close to a first portion of the curved part CV connecting the third and fourth straight parts L3 and L4 to each other. Accordingly, the second and third stopper units SP2 and SP3 are provided at opposite sides in the width direction (±x direction). Therefore, the second and third stopper units SP2 and SP3 do not overlap each other when projecting them in opposite directions in the longitudinal direction (±y direction).

Meanwhile, the third stopper unit SP3 and the first stopper unit SP1 overlap each other when projecting the third and first stopper units in opposite directions in the longitudinal direction (±y direction). Therefore, the first and third stopper units SP1 and SP3 are provided at the same side in the width direction (±x direction).

A seventh stopper ST7 is provided on a lower surface of the fourth straight part L4. The sixth stopper ST6 is provided on the upper surface of the fourth straight part L4, and the seventh stopper ST7 is provided on the lower surface thereof. The sixth and seventh stoppers ST6 and ST7 are provided at opposite sides in the width direction (±x direction). Therefore, the sixth and seventh stopper units SP6 and SP7 do not overlap each other when projecting them in opposite directions in the longitudinal direction (±y direction).

An eighth stopper ST8 is provided on an upper surface of a fifth straight part L5. The eighth stopper ST8 is provided at a position corresponding to the seventh stopper ST7 in the longitudinal direction (±y direction) and brought into contact with the seventh stopper ST7. The elastic part S3-1 of the embodiment 3-1 includes a fourth stopper unit SP4 consisting of the seventh and eighth stoppers ST7 and ST8, between the fourth and fifth straight parts L4 and L5.

The fourth stopper unit SP4 and the third stopper unit SP3 are provided at positions not corresponding to each other in the longitudinal direction (±y direction). Specifically, the third stopper unit SP3 is provided at positions close to a first portion of the curved part CV connecting the third and fourth straight parts L3 and L4 to each other. The fourth stopper unit SP4 is provided at positions close to a second portion of curved part CV connecting the fourth and fifth straight parts L4 and L5 to each other. Accordingly, the third and fourth stopper units SP3 and SP4 are provided at opposite sides in the width direction (±x direction). Therefore, the third and fourth stopper units SP3 and SP4 do not overlap each other when projecting them in opposite directions in the longitudinal direction (±y direction).

Meanwhile, the fourth stopper unit SP4 and the second stopper unit SP2 overlap each other when projecting the fourth and second stopper units in opposite directions in the longitudinal direction (±y direction). Therefore, the second and fourth stopper units SP2 and SP4 are provided at the same side in the width direction (±x direction).

During elastic deformation, the elastic deformation position of the elastic part S3-1 of the embodiment 3-1 is restricted by the plurality of stopper units SP1, SP2, SP3, and SP4 provided between the straight parts L1, L2, L3, L4, and L5.

More specifically, during elastic deformation, the elastic part S3-1 of the embodiment 3-1 is press-deformed in the longitudinal direction (±y direction) due to elastic deformation of the curved parts CV. Accordingly, the first and second stoppers ST1 and ST2 are brought into contact with each other, and the first stopper unit SP1 provides a function of restricting the elastic deformation position of the curved parts CV. When the first and second stoppers ST1 and ST2 are in contact with each other, the curved part CV connecting the first and second straight parts L1 and L2 to each other can no longer be elastically deformed while being pressed in the longitudinal direction (±y direction), and the elastic deformation position is limited.

Furthermore, the third and fourth stoppers ST3 and ST4 are brought into contact with each other, and the second stopper unit SP2 provides the function of restricting the elastic deformation position, and the fifth and sixth stoppers ST5 and ST6 and the seventh and eighth stoppers ST7 and ST8 corresponding in the longitudinal direction (±y direction) are brought into contact with each other, and the third and fourth stopper units SP3 and SP4 provide the function of restricting the elastic deformation position of the curved parts CV.

When the third and fourth stoppers ST3 and ST4 are brought into contact with each other, the curved part CV connecting the second and third straight parts L2 and L3 to each other can no longer be elastically deformed while being pressed in the longitudinal direction (±y direction). Furthermore, When the fifth and sixth stoppers ST5 and ST6 are brought into contact with each other, the curved part CV connecting the third and fourth straight parts L3 and L4 to each other can no longer be elastically deformed while being pressed in the longitudinal direction (±y direction). Furthermore, when the seventh and eighth stoppers ST7 and ST8 are brought into contact with each other, the curved part CV connecting the fourth and fifth straight parts L4 and L5 to each other can no longer be elastically deformed while being pressed in the longitudinal direction (±y direction).

The elastic part S3-1 of the embodiment 3-1 includes the stoppers ST provided on the opposing surfaces of the straight parts L adjacent in the vertical direction. Accordingly, when the elastic part S3-1 of the embodiment 3-1 is elastically deformed in the longitudinal direction (±y direction) due to elastic deformation of the curved part CV connecting the adjacent straight parts L to each other, the opposite stoppers ST are brought into contact with each other and elastic deformation position of the curved part CV is restricted. The elastic part S3-1 of the embodiment 3-1 includes the stoppers ST to prevent excessive pressure (elasticity) deformation, so the breakage problem according to the deformation can be prevented.

### Elastic Part S3-2 of Embodiment 3-2

Next, the elastic part according to an exemplary embodiment 3-2 of the present disclosure (hereinbelow, which refers to the elastic part S3-2 of the embodiment 3-2). In the description below, the elastic part S3-2 of the embodiment 3-2 will be described with a focus on characteristic components compared to the embodiment 1-1 to 3-1 (S1-1, S1-2, S1-3, S1-4, S1-5, S1-6, S1-7, S1-8, S1-9, S1-10, S2, S3-1) and descriptions of similar or identical components will be omitted as much as possible.

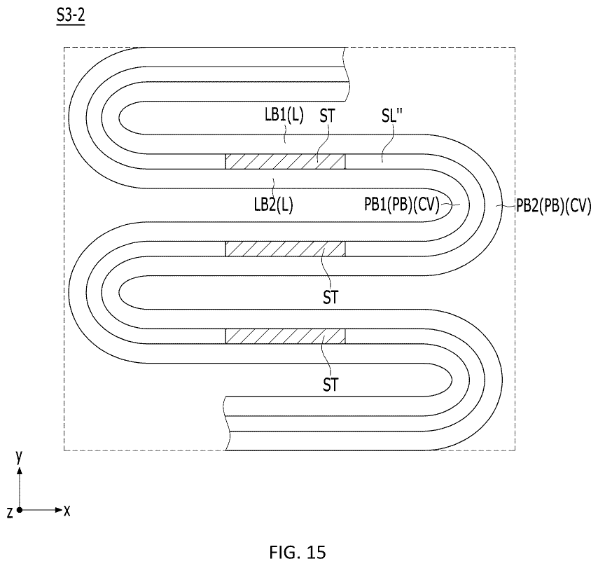

FIG. 15 is an enlarged view illustrating a part of the elastic part S3-2 of the embodiment 3-2.

Referring to FIG. 15, the elastic part S3-2 of the embodiment 3-2 includes the plurality of straight parts L and the plurality of curved parts CV connecting the vertically adjacent straight parts L to each other, a slit part SL″ following the shapes of the vertically adjacent straight parts L and the curved parts CV connecting the straight parts L to each other and successively and formed in the straight parts L and the curved parts CV, and the stoppers ST provided in the straight parts L.

The slit part SL″ is formed through the first and second surfaces of each straight part L and the first and second surfaces of each curved part CV and successively formed along an integrated connected shape of the straight parts L and the curved parts CV. Accordingly, the elastic part S3-2 of the embodiment 3-2 includes the split beam parts PB consisting of the straight parts L and the curved parts CV.

Specifically, each of the straight parts L includes a first straight split beam parts LB1, a second straight split beam parts LB2, and the slit part SL″ provided between the first and second straight split beam parts LB1 and LB2. Each of the curved parts CV includes the first split beam parts PB1, the second split beam parts PB2, and the slit part SL″ provided between the first and second split beam parts PB1 and PB2. The slit part SL″ of the straight parts L and the slit part SL″ of the curved parts CV are formed in a connected single slit part SL″.

The elastic part S3-2 of the embodiment 3-2 includes the stoppers ST between the first and second split beam parts LB1 and LB2. The elastic part S3-2 of the embodiment 3-2 includes a plurality of stoppers ST according to a structure including the straight parts L.

The stoppers ST are provided between the first and second split beam parts LB1 and LB2, so the stoppers are provided in the slit part SL″. Each of the stoppers ST has the longitudinal direction (±y direction) size equal to the longitudinal direction (±y direction) size of the slit part SL″ provided between the first and second split beam parts LB1 and LB2. Accordingly, one surface (lower surface) of the first straight split beam parts LB1 is in contact with an upper surface of each stopper ST, and one surface (upper surface) of the second straight split beam parts LB2 is in contact with a lower surface of each stopper. In other words, the stoppers ST are provided between the first and second split beam parts LB1 and LB2 while being in contact with one surface of each of the first and second straight split beam parts PB.

The elastic part S3-2 of the embodiment 3-2 includes the slit part SL″ that is formed in the same shape as the connected shape of the plurality of straight parts L and the curved parts CV and successively formed in the plurality of straight parts L and the curved parts CV. Each stopper ST is provided in the slit part SL″ provided between the first and second split beam parts LB1 and LB2 to restrict the elastic deformation positions in the longitudinal direction (±y direction) of the first split beam parts PB1 and the second split beam parts PB2 of the curved part CV.

The first split beam parts PB1 is integrally connected to the first straight split beam parts LB1, and the elastic deformation position thereof is restricted by the upper surface of each stopper ST. The second split beam parts PB2 is integrally connected to the second straight split beam parts LB2, and the elastic deformation position thereof is restricted by the lower surface of each stopper ST.

Accordingly, it is possible to prevent the elastic part S3-2 of the embodiment 3-2 from being damaged due to excessive pressure deformation.

### Elastic Part S3-3 of Embodiment 3-3

Next, the elastic part according to an exemplary embodiment 3-3 of the present disclosure (hereinbelow, which refers to the elastic part S3-3 of the embodiment 3-3). In the description below, the elastic part S3-3 of the embodiment 3-3 will be described with a focus on characteristic components compared to the embodiment 1-1 to 3-2 (S1-1, S1-2, S1-3, S1-4, S1-5, S1-6, S1-7, S1-8, S1-9, S1-10, S2, S3-1, S3-2) and descriptions of similar or identical components will be omitted as much as possible.

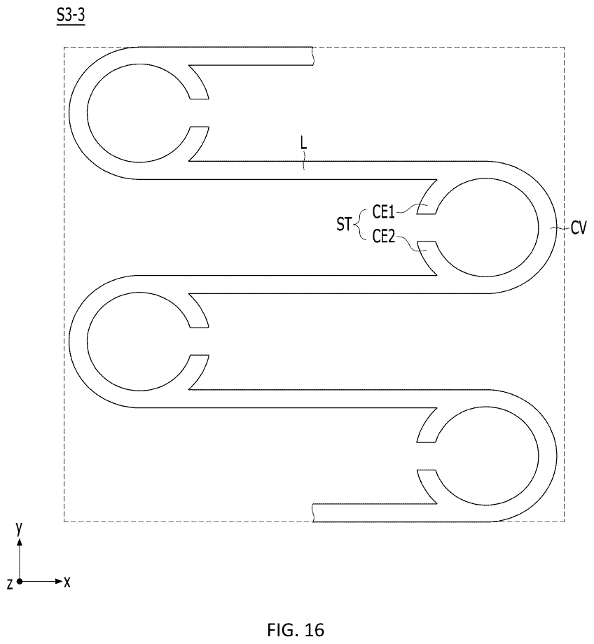

FIG. 16 is an enlarged view illustrating a part of the elastic part S3-3 of the embodiment 3-3.

The elastic part S3-3 of the embodiment 3-3 includes the plurality of straight parts L, the curved parts CV connecting the vertically adjacent straight parts L, and the stoppers ST provided in the curved parts CV.

Referring to FIG. 16, the elastic part S3-3 of the embodiment 3-3 includes a first curvature extension part CE1 extending with curvature inward in the width direction (±x direction), from a first portion of the curved part CV connected to one end of an upper straight part among the plurality of straight parts L, and a second curvature extension part CE2 extending with curvature inward in the width direction(±x direction), from a second portion of the curved part CV connected to one end of a lower straight part L.

A spacing is formed between the first and second curvature extension parts CE1 and CE2. The elastic part S3-3 of the embodiment 3-3 includes the first and second curvature extension parts CE1 and CE2, so the curved part CV has a cut portion in the inner portion in the width direction (±x direction). The cut portion of the curved part CV has the longitudinal directional (±y direction) size equal to the spacing between the first and second curvature extension parts CE1 and CE2.

The elastic part S3-3 of the embodiment 3-3 has the stoppers ST provided by the first and second curvature extension parts CE1 and CE2. In other words, the elastic part S3-3 of the embodiment 3-3 includes the curved parts CV each including the first and second curvature extension parts CE1 and CE2, so the elastic part S3-3 includes the curved parts CV that includes the cut portion on the inner portion in the width direction (±x direction), the cut portion having a longitudinal directional (±y direction) size by the spacing between the first and second curvature extension parts CE1 and CE2. For the elastic part S3-3 of the embodiment 3-3, each stopper ST is formed in each curved part CV by the first and second curvature extension parts CE1 and CE2 in which the spacing is provided in the longitudinal direction (±y direction). Therefore, each stopper ST is provided in each curved part CV by the first and second curvature extension parts CE1 and CE2 in which the spacing is provided in the longitudinal direction (±y direction).

When pressure is applied to the elastic part S3-3 of the embodiment 3-3, each curved part CV is pressed in the longitudinal direction (±y direction) and elastically deformed. Accordingly, the spacing between the first and second curvature extension parts CE1 and CE2 is reduced, which allows the first and second curvature extension parts CE1 and CE2 to be brought into contact with each other. Accordingly, the elastic deformation position of each curved part CV in the longitudinal direction (±y direction) is restricted.

For the elastic part S3-3 of the embodiment 3-3, the first and second curvature extension parts CE1 and CE2 having the spacing in the longitudinal direction (±y direction) are provided in each curved part CV, thereby restricting an elastic deformation length of each curved part CV by the spacing between the first and second curvature extension parts CE1 and CE2. Each curved part CV is elastically deformed until the first and second curvature extension parts CE1 and CE2 are brought into contact with each other, and the elastic deformation position is restricted due to the contact between the first and second curvature extension parts CE1 and CE2. Accordingly, the breakage problem can be prevented by preventing excessively elastic deformation of the elastic part S3-3 of the embodiment 3-3.

### Elastic Part S4-1 of Embodiment 4-1

Next, the elastic part according to an exemplary embodiment 4-1 of the present disclosure (hereinbelow, which refers to the elastic part S4-1 of the embodiment 4-1). In the description below, the elastic part S4-1 of the embodiment 4-1 will be described with a focus on characteristic components compared to the embodiment 1-1 to 3-3 (S1-1, S1-2, S1-3, S1-4, S1-5, S1-6, S1-7, S1-8, S1-9, S1-10, S2, S3-1, S3-2, S3-3) and descriptions of similar or identical components will be omitted as much as possible.

FIG. 14 is an enlarged view illustrating a part of the elastic part S4-1 of the embodiment 4-1.

The elastic part S4-1 of the embodiment of 4-1 includes the plurality of straight parts L, the plurality of curved parts CV each connecting vertically adjacent straight parts L, and a groove part HP formed in each curved part CV.

The groove part HP is formed by cutting an inner surface of each curved part CV in the width direction (±x direction) and formed through the first surface and the second surface of each curved part CV. The groove part HP is provided in a central portion of each curved part CV in the longitudinal direction (±y direction) and provided as a cut portion formed in the inner surface of each curved part CV in the width direction (±x direction).

The groove part HP has curvature on an outer portion in the width direction (±x direction), and having an opening on an inner portion thereof. For the elastic part S4-1 of the embodiment of 4-1, the groove part HP is formed on the inner surface of each curved part CV, and the groove part HP provides the cut portion on at least a portion of the inner surface of each curved part CV.

As the elastic part S4-1 of the embodiment of 4-1 includes the groove part HP on the inner surface of each curved part CV, the beam width PW in the width direction(±x direction) at the central portion of each curved part CV is reduced. Furthermore, the groove part HP allows the elastic part S4-1 of the embodiment of 4-1 to have a space receiving elastic deformation of each curved part CV in the longitudinal direction (±y direction). Accordingly, the elastic part S4-1 of the embodiment of 4-1 can be elastically deformed more easily.

### Elastic Part S of Embodiment 4-2

Next, the elastic part according to an exemplary embodiment 4-2 of the present disclosure (hereinbelow, which refers to the elastic part S4-2 of the embodiment 4-2). In the description below, the elastic part S of the embodiment 4-2 will be described with a focus on characteristic components compared to the embodiment 1-1 to 4-1 (S1-1, S1-2, S1-3, S1-4, S1-5, S1-6, S1-7, S1-8, S1-9, S1-10, S2, S3-1, S3-2, S3-3, S4-1) and descriptions of similar or identical components will be omitted as much as possible.

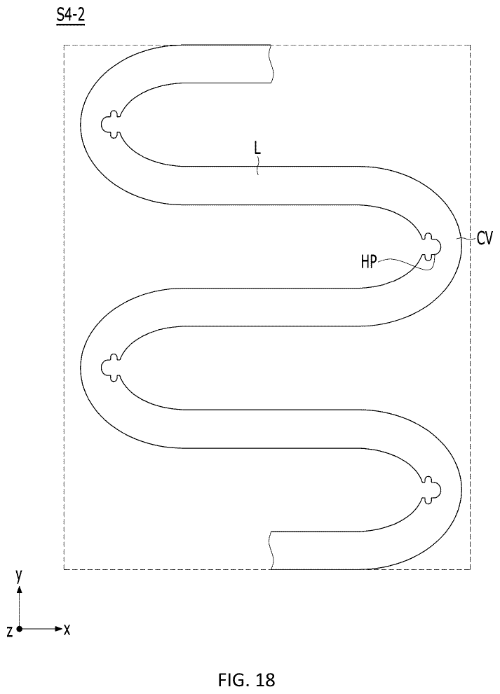

FIG. 18 is an enlarged view illustrating a part of the elastic part S of the embodiment 4-2.

The elastic part S of the embodiment of 4-2 includes the plurality of straight parts L, the plurality of curved parts CV each connecting vertically adjacent straight parts L, and a groove part HP formed in each curved part CV. The elastic part S of the embodiment 4-2 has a difference in that the shape of the groove part HP of the elastic part S of the embodiment 4-2 is different from the shape of the groove part HP of the elastic part S4-1 of the embodiment of 4-1.

Referring to FIG. 18, the groove part HP is a cut portion formed on the inner surface of each curved part CV, and includes a groove part (hereinbelow, which refers to a width-directional concave portion) concave toward an outer side in the width direction(±x direction), and a groove part (hereinbelow, which refers to a longitudinal concave portion) communicating with the width-directional concave portion and formed concavely in the longitudinal direction (±y direction) at a position close to the inner surface of each curved part CV.

Therefore, the elastic part S of the embodiment 4-2 includes the groove part HP that is concave in the width direction (±x direction) and concave in the longitudinal direction (±y direction) in a perpendicular direction to the width-directional concave portion. The longitudinal directional (±y direction) size and the width directional (±x direction) size at the inner portion of each curved part CV may be formed to be relatively small. Accordingly, when the elastic part S of the embodiment 4-2 is elastically deformed, elastic deformation at the inner portion of each curved part CV can be performed more easily, thereby preventing the breakage problem.

Although the preferred embodiments of the present disclosure have been described for illustrative purposes, those skilled in the art will appreciate that various modifications, additions and substitutions are possible, without departing from the scope and spirit of the present disclosure as disclosed in the accompanying claims.

### DESCRIPTION OF REFERENCE NUMERALS

100: electrically conductive contact pin
110: first connection part
120: second connection part
130: support part
S: elastic part
SL: slit part
ST: stopper
HP: groove part

1. An electrically conductive contact pin comprising an elastic part, wherein the elastic part comprises:
a plurality of straight parts;
a plurality of curved parts each connecting upper and lower adjacent straight parts to each other among the plurality of straight parts; and
a slit part formed through a front surface and a second surface of each of the curved parts,
wherein each of the curved parts comprises a plurality of split beam parts formed of the slit part.

2. The electrically conductive contact pin of claim 1, wherein beam widths of the plurality of split beam parts are identical to each other.

3. The electrically conductive contact pin of claim 1, wherein beam widths of the split beam parts are larger in a direction from an inner part of each curved part to an outer part of each curved part.

4. The electrically conductive contact pin of claim 1, wherein the slit part comprises a plurality of slit parts,
wherein among the plurality of slit parts, a slit part provided at an inner part of each curved part has a larger available space width than a slit part provided in an outer part of each curved part.

5. The electrically conductive contact pin of claim 1, wherein the split beam parts have radii of curvature that are larger in a direction from an inner part of each curved part to an outer part of each curved part.

6. The electrically conductive contact pin of claim 5, wherein the sum of beam widths of the split beam parts is equal to the beam width of each of the straight parts.

7. The electrically conductive contact pin of claim 1, wherein each of the split beam parts has a bent portion having curvature, and a beam width of the bent portion is smaller than a beam width of a surrounding portion.

8. The electrically conductive contact pin of claim 1, wherein a beam width of each of the straight parts is less than a beam width of each of the curved parts.

9. An electrically conductive contact pin comprising an elastic part, wherein the elastic part comprises:
a plurality of straight parts;
a plurality of curved parts each connecting upper and lower adjacent straight parts to each other among the plurality of straight parts; and
a stopper provided in at least one of the straight and curved parts and restricting an elastic deformation position of the elastic part.

10. An electrically conductive contact pin comprising an elastic part, wherein the elastic part comprises:
a plurality of straight parts;
a plurality of curved parts each connecting upper and lower adjacent straight parts to each other among the plurality of straight parts; and
a groove part providing a cut portion on an inner surface of each of the curved parts and formed through a first surface and a second surface of each of the curved parts.
